(19) United States
(12) Patent Application Publication
(10) Pub. No.: US 2010/0078688 A1
(43) Pub. Date: Apr. 1, 2010

(54) NITRIDE SEMICONDUCTOR DEVICE, NITRIDE SEMICONDUCTOR PACKAGE, AND METHOD FOR MANUFACTURING NITRIDE SEMICONDUCTOR DEVICE

(75) Inventors: Hirotaka Otake, Kyoto (JP); Shin Egami, Kyoto (JP); Hiroaki Ohta, Kyoto (JP)

Correspondence Address: RABIN & Berdo, PC, 1101 14TH STREET, NW, SUITE 500, WASHINGTON, DC, 20005, US

(73) Assignee: ROHM CO., LTD, Kyoto (JP)

(21) Appl. No.: 12/524,532

(22) PCT Filed: Jan. 16, 2008
(86) PCT No.: PCT/JP2008/050457

§ 371 Date: Nov. 12, 2009

(30) Foreign Application Priority Data
Jan. 26, 2007 (JP) 2007-016775
Mar. 6, 2007 (JP) 2007-056429

(51) Int. Cl. H01L 29/20; H01L 23/48; H01L 29/78

(52) U.S. Cl. 257/288; 257/690; 257/76; 257/E23.01; 257/E29.089; 257/E29.255

(57) ABSTRACT

A nitride semiconductor device of the present invention includes: a nitride semiconductor laminated structure including an n-type first layer, a second layer that is laminated on the first layer and contains a p-type impurity, and an n-type third layer laminated on the second layer, each layer of the nitride semiconductor laminated structure being made of a Group III nitride semiconductor, and having a wall surface extending from the first, second, to third layers; a fourth layer that is formed on the wall surface in the second layer and that has a different conductive characteristic from that of the second layer; a gate insulating film formed to contact the fourth layer; and a gate electrode formed as facing the fourth layer with the gate insulating film being sandwiched between the gate electrode and the fourth layer.

### TECHNICAL FIELD

The present invention relates to a nitride semiconductor device using a Group III nitride semiconductor, a nitride semiconductor package using the nitride semiconductor device, and a method for manufacturing a nitride semiconductor device.

### BACKGROUND ART

Conventionally, a power device using a silicon semiconductor is used for a power amplifier circuit, a power supply circuit, a motor drive circuit, etc.

From a theoretical limitation of the silicon semiconductor, however, high withstand voltage, low resistance, and high speed of the silicon device have almost reached their limits. As a result, satisfying market demands have gradually become difficult.

Therefore, studies are being made in the development of a GaN device having characteristics such as high withstand voltage, high-temperature operation, a large current density, high-speed switching, and low ON resistance (for example, see Non-patent document 1).

Non-patent document 1: “Mou hikaru dakejyanai, kiki no shinka no ura ni GaN (No Longer Just Emitting Light, GaN Supports Device Evolution)” authored by Satoshi Okubo, Jun. 5, 2006, Nikkei Electronics, pp. 51-60

### DISCLOSURE OF THE INVENTION

### Problems to be Solved by the Invention

GaN devices that have been proposed attempt to increase the gate withstand voltage by making a gate insulating film thick. Also, an MIS (Metal Insulator Semiconductor) type field effect transistor (MISFET) is designed so that when an acceptor concentration of a p-type semiconductor is increased, reach through breakdown is prevented and a withstand voltage is increased.

In such a GaN device, however, there is a flaw that while the high withstand voltage can be realized, because of two factors (thick gate insulating film and high acceptor concentration), the gate threshold value voltage is increased. As a result, there arises a problem that a satisfactory transistor operation cannot be performed, and thus, such a GaN device is not always suitable for a power device.

Therefore, an object of the present invention is to provide a nitride semiconductor device capable of securing a high withstand voltage property and also realizing a low gate threshold value voltage and a method for manufacturing the same.

Also, another object of the present invention is to provide a nitride semiconductor package including such a nitride semiconductor device.

### Means for Solving the Problem

A nitride semiconductor device according to one aspect of the present invention includes: a nitride semiconductor laminated structure including an n-type first layer, a second layer that contains a p-type impurity and that is laminated on the first layer, and an n-type third layer laminated on the second layer, each layer of the nitride semiconductor laminated structure being made of a Group III nitride semiconductor, the nitride semiconductor laminated structure having a wall surface extending from the first, second, to third layers; a fourth layer being formed on the wall surface in the second layer and having a different conductive characteristic from that of the second layer; a gate insulating film formed so as to contact the fourth layer; and a gate electrode formed as facing the fourth layer with the gate insulating film being sandwiched between the gate electrode and the fourth layer.

According to this configuration, when an n-type first layer, a second layer that contains a p-type impurity and that has conductive characteristics, and an n-type third layer are laminated, a nitride semiconductor laminated structure having an npn structure is formed, for example. Also, the nitride semiconductor laminated structure is formed with a wall surface extending from the first, second, to third layers, and a semiconductor surface section of the second layer of which the surface is exposed by the formation of the wall surface is formed with a fourth layer being a region having a different conductive characteristic from that of the second layer. Then, a gate insulating film is formed so as to contact the fourth layer, and a gate electrode is formed so as to oppose this region with the gate insulating film to be sandwiched between the gate electrode and the region.

Thereby, when a drain electrode is arranged so as to be electrically connected to first layer and a source electrode is arranged so as to be electrically connected to a third layer, for example, a vertical MIS (Metal Insulator Semiconductor) type field effect transistor can be obtained. In addition, it is noted that it may be sufficient that the drain electrode and the source electrode are electrically connected to the first layer and the third layer, respectively, and two or more semiconductor layers having a different composition or impurity are laminated between the electrode and the semiconductor layer.

In this case, a region in which a channel is formed is a fourth layer, which is a region having a different conductive characteristic from that of a second layer, and thus, when this region is a p-type semiconductor having an acceptor concentration lower than that of the second layer, for example, as compared to a case that conductive characteristics of the region in which the channel is formed is the same as that of the second layer, a gate voltage value necessary for the formation of an inversion layer can be kept low. The factor that determines the voltage value of the reach through breakdown is the acceptor concentration of the second layer, and as a result, the gate threshold value voltage can be decreased while securing the high withstand voltage property of the transistor, thereby realizing a satisfactory power device.

When the nitride semiconductor device is used as a basic structure as the vertical MIS type field effect transistor as illustrated above, a normally-off operation, that is, an operation for turning a source-to-drain into an off status when no bias is applied to a gate electrode, can be easily realized. Moreover, the MIS type field effect transistor has a vertical structure, and thus, a large amount of current can also easily flow, and when a film thickness of the first layer is thickened, a high withstand voltage property can also be easily secured. Therefore, an effective power device can be provided. Of course, since the field effect transistor is configured by the Group III nitride semiconductor layer, characteristics such as high withstand voltage, a high-temperature operation, a large current density, high-speed switching, and a low ON resistance can also be received as compared to a device using a silicon semiconductor. In particular, an operation of high withstand voltage at low loss is possible, and thus, a satisfactory power device can be realized.

The Group III nitride semiconductor is a semiconductor that is obtained by combining a Group III element and nitrogen, and representative examples thereof include aluminum nitride (AlN), gallium nitride (GaN), and indium nitride (InN). Generally, it can be expressed as AlₓIn_{y}Ga_{i-x-y}N (0≦x≦1, 0≦y1, 0≦x+y≦1).

For example, an operation of a case of configuring an MIS type field effect transistor in which the conductive characteristic of a second layer is a p-type and the conductive characteristic of a fourth layer is a p-type having an acceptor concentration lower than that of the second layer will be described.

In this case, between the source and the drain, a bias in which a drain side is positive is applied. At this time, a p-n junction at an interface between the first and second layers is applied with a reverse voltage, and thereby, a cutoff status is established between the source and the drain.

From this status, when a bias voltage not less than a predetermined voltage value (gate threshold value voltage) which is positive with respect to the second layer is applied to the gate electrode, electrons are induced near the surface of the fourth layer thereby to form an inversion layer. Via the inversion layer, conduction is provided between the first and third layers. Thus, conduction is provided between the source and drain. At this time, an acceptor concentration of the fourth layer forming a region where a channel is formed is lower than that of the second layer, and thus, it is possible to induce the electrons to the fourth layer by a lower gate threshold value voltage. When an impurity concentration of the fourth layer is appropriately defined, if an appropriate bias is applied to the gate electrode, conduction is provided between the source and the drain while if the bias is not applied to the gate electrode, a cutoff status is achieved between the source and the drain. That is, a normally-off operation is realized.

In addition, the fourth layer, which is illustrated above, may be a p-type semiconductor having an acceptor concentration lower than that of the above-described second layer. Moreover, the fourth layer may be an n-type semiconductor. When the fourth layer is the n-type semiconductor, to realize the normally-off operation of the field effect transistor, a concentration of the n-type impurity can be properly controlled. Moreover, the fourth layer may be an i-type semiconductor. The fourth layer may be a semiconductor containing an n-type impurity and a p-type impurity.

It is preferable that in the nitride semiconductor device, the gate insulating film be formed so as to contact the first layer or the third layer on the wall surface, and the gate electrode be formed as facing the first or third layer on the wall surface with the gate insulating film being sandwiched between the gate electrode and the first or third layer.

By this configuration, an MIS structure can be configured to a depletion layer expanded to the first or third layer above or below the fourth layer. Thereby, upon the formation of a channel in the fourth layer, an accumulation layer is also formed to the depletion layer expanding to the first or third layer, and thus, a current can flow without interference by the depletion layer during on time. As a result, an ON resistance can be further reduced.

For example, in the npn vertical structure, the depletion layer expanding to an n-type layer by an internal potential is expressed as in the following equation by use of a one-sided step junction approximation.

W=\sqrt{2∈ₛV_{bi}/qN_{D}} [Equation 1]

(W: depletion layer width; ∈ₛ: dielectric constant of Group III nitride semiconductor; V_{bi}: internal potential of p-n junction; q: elementary charge; and N_{D}: impurity concentration of n-type layer)

In the equation, assuming that the Group III nitride semiconductor is gallium nitride (GaN);

the impurity concentration of the n-type first layer is N_{D}=5×10¹⁶ cm⁻³;

the impurity concentration of the p-type second layer is 1×10¹⁸ Cm⁻³; and

the impurity concentration of the n-type third layer is 3×10¹⁸ cm⁻³.

In this case, the depletion layer width expanding to the n-type first layer is W=0.25 (μm), where elementary charge q=1.6×10⁻¹⁹ (C) dielectric constant ∈ₛ=9.5×8.85×10⁻¹⁴ (F/CM) and internal potential V_{bi}=3 (V).

At this time, when the wall surface is formed in a range not less than 0.25 μm from the p-n junction at least between the p-type second layer and the n-type first layer and the MIS structure is formed within this range, the current can flow without interference by the depletion layer during on time.

It is preferable that the first layer includes a lower layer and an upper layer that has an impurity concentration smaller than that of the lower layer and that is crossed by the lower layer and the second layer.

According to this configuration, when a transistor is operated in a saturation region, the depletion layer can be expanded to an upper layer side of the first layer. This reduces the expansion of the depletion layer to the second layer side, thereby suppressing reach through breakdown.

Preferably, the nitride semiconductor device further includes a drain electrode electrically connected to the first layer and a source electrode electrically connected to the third layer. By this configuration, a vertical MIS type field effect transistor that provides the above-described effect can be realized.

Preferably, the nitride semiconductor device includes a trench that reaches from the third layer through the second layer to the first layer and that has a side wall configuring the wall surface; and a second trench that is formed so as to reach at least the first layer and that is different from the trench, in which on a bottom surface of the second trench, a drain electrode is formed.

According to this configuration, a trench that reaches from the third layer through the second layer to the first layer and that has a side wall configuring the wall surface is formed. Therefore, the gate insulating film and the gate electrode are formed within the trench.

A second trench in which the drain electrode is formed is formed separately of the trench in which the gate electrode is formed. Therefore, it can be controlled so that the second trench for forming the drain electrode is formed in a deep shape and the trench for forming the gate is formed in a shallow shape, respectively. Due to this control, a superficial area of the first layer opposing the gate electrode can be decreased, and thus, an interface charge in the first layer can be diminished. As a result, an off-leak current can be made smaller, and an ON resistance can be reduced. Moreover, the source, the gate, and the drain are not placed in this order on the same surface, and thus, off characteristics can be improved.

Preferably, the nitride semiconductor device further includes a source electrode electrically connected to the first layer and a drain electrode electrically connected to the third layer. By this configuration also, a vertical MIS type field effect transistor that provides the above-described effect can be realized.

Preferably, in the nitride semiconductor device, the nitride semiconductor laminated structure is formed on an insulative substrate.

A typical insulative substrate is a sapphire (Al₂O₃) substrate. Even when such an insulative substrate is used, if the drain electrode and the source electrode are caused to directly come into contact with the first layer, an n-type Group III nitride semiconductor layer is further arranged between the insulative substrate and the first layer, or this layer is contacted by the drain electrode and the source electrode, it becomes possible to electrically connect the first layer with the drain electrode and the source electrode.

Preferably, in the nitride semiconductor device, the drain electrode or the source electrode is formed on a surface of the nitride semiconductor laminated structure of which the surface is exposed by removing the insulative substrate. In this configuration, even when the insulative substrate is used, a vertical MIS system field effect transistor can be realized. Moreover, the insulative substrate is removed, and thus, a resistance of a substrate during a transistor operation can be diminished. As a result, a satisfactory transistor operation can be obtained.

Preferably, in the nitride semiconductor device, the nitride semiconductor laminated structure is formed on one surface of an electrically conductive substrate, and the drain electrode or the source electrode is formed on an alternate surface of the electrically conductive substrate.

A typical electrically conductive substrate is GaN and SiC. In this configuration, on one surface of the electrically conductive substrate, the nitride semiconductor laminated structure is placed, and on an alternate surface of the electrically conductive substrate, the drain electrode or the source electrode is connected. Thereby, the drain electrode or the source electrode is electrically connected to the first layer. As a result, a current flows through a wide range of the nitride semiconductor laminated structure, and thus, a current constriction can be suppressed, and also, the high withstand voltage can be achieved.

The gate insulating film may be configured of a silicon oxide or a gallium oxide, or of both of the oxides.

The first, second, and third layers may be so laminated that a c-plane (0001) is a main surface.

A plane orientation of the wall surface of the nitride semiconductor laminated structure may be a plane inclined by an angle of 15 to 90 degrees relative to the main surface (c-plane (0001)). In particular, the wall surface of the nitride semiconductor laminated structure preferably is a semi-polar plane ((10-11), (10-13), (11-22), etc.) or a non-polar plane such as an m-plane (10-10) and an a-plane (11-20).

In this way, when the plane orientation of the wall surface of the nitride semiconductor laminated structure is set to a plane orientation different from the c-plane (0001), it becomes possible to suppress the generation of a redundant polarization charge resulting from a spontaneous polarization of the second layer near the interface between the second layer and the gate insulating film. In particular, the non-polar plane and the semi-polar plane are a very stable plane of which crystal symmetry is high, thereby diminishing an interface charge. Thus, a satisfactory interface can be obtained.

Preferably, the third layer is a layer obtained by laminating a plurality of layers having different compositions.

According to this configuration, when a GaN layer is laminated on a near side of the substrate out of the third layer, and on top of the GaN layer, an Al_{0.2}Ga_{0.8}N layer is laminated, for example, a two-dimensional electron gas (sheet carrier 1×10¹³ cm⁻³; electron mobility 1000 cm²/V·s) is formed near a boundary portion between these two layers. Thus, a resistance parasitic on the third layer can be lowered and an ON resistance of the transistor can be reduced. It is noted that a plurality of layers having different compositions may include an AlGaN superlattice layer and a plurality of AlGaN layers having different compositions.

Preferably, the first layer is a layer obtained by laminating a plurality of layers having different compositions.

According to this configuration, when a GaN layer is laminated on a near side of the substrate out of the first layer, and on top of the GaN layer, an Al_{0.2}Ga_{0.8}N layer is laminated, for example, a two-dimensional electron gas (sheet carrier 1×10¹³ cm⁻³; electron mobility 1000 cm²/V·s) is formed near a boundary portion between these two layers. Thus, a resistance parasitic on the first layer can be lowered and an ON resistance of the transistor can be reduced. An ON resistance of the transistor can be reduced. It is noted that a plurality of layers having different compositions may include an AlGaN superlattice layer and a plurality of AlGaN layers having different compositions.

A nitride semiconductor device according to another aspect of the present invention includes: a nitride semiconductor laminated structure including an n-type first layer, a second layer that contains a p-type impurity and that is laminated on the first layer, and an n-type third layer laminated on the second layer, each layer of the nitride semiconductor laminated structure being made of a Group III nitride semiconductor, the nitride semiconductor laminated structure having a wall surface extending from the first, second, to third layers; a fourth layer being formed on the wall surface in the second layer and having a different conductive characteristic from that of the second layer; a gate insulating film formed so as to contact the fourth layer; and a gate electrode formed as facing the fourth layer with the gate insulating film being sandwiched between the gate electrode and the fourth layer. The gate insulating film contains a nitride and an oxide, and a insulating film contacting the wall surface is a nitride. More specifically, the nitride may be a silicon nitride, for example, and the oxide may be a silicon oxide, for example.

According to this configuration, when the insulating film contacting the wall surface is a nitride, an interface charge on the wall surface can be suppressed and an off-leak current can be reduced. Moreover, when the gate insulating film is configured only by the nitride (silicon nitride), the withstand voltage is low. However, when the gate insulating film is configured to contain the nitride and the oxide, the withstand voltage can be improved. As a result, the transistor operation can be improved. In addition, an oxynitride (for example, a silicon oxynitride) may be used together, as needed.

Preferably, the gate insulating film as described above is film-deposited by an ECR (Electron Cyclotron Resonance) sputtering method. When the silicon nitride film film-deposited by the ECR sputtering method is used, a better transistor operation can be performed.

Also, the gate insulating film preferably is a insulating film formed continuously without a wafer formed thereon with the nitride semiconductor device being extracted from a deposition apparatus.

The nitride semiconductor package of the present invention includes a package housing, formed of an electrically conductive material, for loading and mounting a semiconductor element; and the nitride semiconductor device of which a source electrode is loaded on the package housing so as to come into contact with the package housing.

According to this configuration, in the nitride semiconductor device, its source electrode is loaded to come into contact with the package housing. Therefore, when the package housing is grounded, the source electrode can be grounded via this package housing. That is, it is not necessary to arrange a ground wire (for grounding the source electrode) for connecting the source electrode and the package housing, and thus, the structure of the package can be simplified. Further, when the package thus simplified is used, its assembly is easily performed.

A method for manufacturing a nitride semiconductor device of the present invention, includes: a step of forming on a substrate a nitride semiconductor laminated structure having a laminated structure including an n-type first layer, a second layer that contains a p-type impurity, and an n-type third layer, each layer of the nitride semiconductor being made of a Group III nitride semiconductor; a wall surface forming step of forming a wall surface extending from the first, second, to third layers; a fourth layer forming step of forming a fourth layer being a region of which conductive characteristic is different from that of the second layer, on a semiconductor surface section of the second layer exposed at the wall surface forming step; a gate insulating film forming step of forming a gate insulating film to contact the fourth layer; and a step of forming a gate electrode to oppose the fourth layer with the gate insulating film being sandwiched between the gate electrode and the fourth layer. By this method, the nitride semiconductor device can be fabricated.

The fourth layer forming step may include a transforming step of transforming the semiconductor surface section of the second layer.

The transforming step may include a step of irradiating the semiconductor surface section of the second layer with plasma. Also, the transforming step may include a step of irradiating the semiconductor surface section of the second layer with an electron beam. Further, the transforming step may include a step of ion implanting the semiconductor surface section of the second layer.

In addition, preferably, the gate insulating film forming step is performed by an ECR sputtering method, and the transforming step includes a step of transforming the semiconductor surface of the second layer during the gate insulating film forming step by the ECR sputtering method. According to this configuration, the gate insulating film forming step and the transforming step (fourth layer forming step) are performed simultaneously. In this case also, the semiconductor surface of the second layer can be transformed.

Also, preferably, the gate insulating film forming step is performed by a magnetron sputtering method, and the transforming step includes a step of transforming the semiconductor surface of the second layer during the gate insulating film forming step by the magnetron sputtering method. According this configuration, the gate insulating film forming step and the transforming step (fourth layer forming step) are performed simultaneously. In this case also, the semiconductor surface of the second layer can be transformed.

Also, preferably, the fourth layer forming step includes a step of growing from the wall surface a semiconductor having conductive characteristics different from those of the second layer. According to this configuration, the semiconductor grown from the wall surface results in the fourth layer formed on the semiconductor surface of the second layer. In this case also, the nitride semiconductor device can be fabricated.

The wall surface forming step may include a step of etching the first, second, and third layer by dry etching.

These and other objects, features and effects of the present invention will be more apparent from the following embodiments described with reference to the accompanying drawings.

### BRIEF DESCRIPTION OF THE DRAWINGS

FIG. 1 is a diagrammatic cross-sectional view for describing the structure of a field effect transistor according to a first embodiment of the present invention.

FIG. 2A is a diagrammatic cross-sectional view showing a method for manufacturing the field effect transistor in FIG. 1 according to a sequence of steps.

FIG. 2B is a diagram showing a step subsequent to that in FIG. 2A.

FIG. 2C is a diagram showing a step subsequent to that in FIG. 2B.

FIG. 2D is a diagram showing a step subsequent to that in FIG. 2C.

FIG. 2E is a diagram showing a step subsequent to that in FIG. 2D.

FIG. 3A is a diagrammatic cross-sectional view showing another method for manufacturing the field effect transistor in FIG. 1 according to a sequence of steps.

FIG. 3B is a diagram showing a step subsequent to that in FIG. 3A.

FIG. 3C is a diagram showing a step subsequent to that in FIG. 3B.

FIG. 3D is a diagram showing a step subsequent to that in FIG. 3C.

FIG. 3E is a diagram showing a step subsequent to that in FIG. 3D.

FIG. 4 is a diagrammatic cross-sectional view for describing the structure of a field effect transistor according to a second embodiment of the present invention.

FIG. 5A is a diagrammatic cross-sectional view showing a method for manufacturing the field effect transistor in FIG. 4 according to a sequence of steps.

FIG. 5B is a diagram showing a step subsequent to that in FIG. 5A.

FIG. 5C is a diagram showing a step subsequent to that in FIG. 5B.

FIG. 5D is a diagram showing a step subsequent to that in FIG. 5C.

FIG. 5E is a diagram showing a step subsequent to that in FIG. 5D.

FIG. 6 is a diagrammatic cross-sectional view for describing the structure of a field effect transistor according to a modified example of the field effect transistor shown in FIG. 4.

FIG. 7 is a cross-sectional view showing a status where the field effect transistor shown in FIG. 6 is mounted on a package housing.

FIG. 8 is a diagrammatic cross-sectional view for describing the structure of a field effect transistor according to a third embodiment of the present invention.

FIG. 9A is a diagrammatic cross-sectional view showing a method for manufacturing the field effect transistor in FIG. 8 according to a sequence of steps.

FIG. 9B is a diagram showing a step subsequent to that in FIG. 9A.

FIG. 9C is a diagram showing a step subsequent to that in FIG. 9B.

FIG. 9D is a diagram showing a step subsequent to that in FIG. 9C.

FIG. 9E is a diagram showing a step subsequent to that in FIG. 9D.

FIG. 9F is a diagram showing a step subsequent to that in FIG. 9E.

FIG. 9G is a diagram showing a step subsequent to that in FIG. 9F.

FIG. 10 is a diagrammatic cross-sectional view for describing the structure of a field effect transistor according to a fourth embodiment of the present invention.

FIG. 11A is a diagrammatic cross-sectional view showing a method for manufacturing the field effect transistor in FIG. 10 according to a sequence of steps.

FIG. 11B is a diagram showing a step subsequent to that in FIG. 11A.

FIG. 11C is a diagram showing a step subsequent to that in FIG. 11B.

FIG. 11D is a diagram showing a step subsequent to that in FIG. 11C.

FIG. 11E is a diagram showing a step subsequent to that in FIG. 11D.

FIG. 11F is a diagram showing a step subsequent to that in FIG. 11E;

FIG. 12 is a diagrammatic cross-sectional view for describing the structure of a field effect transistor according to a fifth embodiment of the present invention.

FIG. 13 is a diagrammatic cross-sectional view for describing the structure of a field effect transistor according to a sixth embodiment of the present invention.

FIG. 14 is a diagrammatic cross-sectional view for describing the structure of a field effect transistor according to a seventh embodiment of the present invention.

FIG. 15A is a diagrammatic cross-sectional view showing a method for manufacturing the field effect transistor in FIG. 14 according to a sequence of steps.

FIG. 15B is a diagram showing a step subsequent to that in FIG. 15A.

FIG. 15C is a diagram showing a step subsequent to that in FIG. 15B.

FIG. 15D is a diagram showing a step subsequent to that in FIG. 15C.

FIG. 15E is a diagram showing a step subsequent to that in FIG. 15D.

FIG. 15F is a diagram showing a step subsequent to that in FIG. 15E.

FIG. 16 is a diagrammatic cross-sectional view for describing the structure of a field effect transistor according to an eighth embodiment of the present invention.

FIG. 17 is a graph showing simulation data indicating gate voltage-drain current characteristics of field effect transistors of Example 1 and Comparative Example 1.

FIG. 18 is a graph indicating gate voltage-drain current characteristics of field effect transistors of Example 2 and Comparative Example 2.

FIG. 19 is a graph indicating gate voltage-drain current characteristics of field effect transistors of Example 3 and Comparative Example 2.

### DESCRIPTION OF THE REFERENCE NUMERALS

1 . . . nitride semiconductor laminated structure; 2 . . . n-type GaN layer; 3 . . . p-type GaN layer; 4 . . . n-type GaN layer; 6 . . . drain electrode; 7 . . . wall surface; 8 . . . gate insulating film; 9 . . . gate electrode; 10 . . . region; 11 . . . source electrode; 12 . . . substrate; 16 . . . n-type GaN layer; 17 . . . gate insulating film; . . . package housing; 20 . . . substrate; 21 . . . electrically conductive substrate; 30 . . . trench; 81 . . . silicon nitride film; 82 . . . silicon oxide film; 200 . . . n-type nitride semiconductor layer; 201 . . . n-type GaN layer; 202 . . . n-type GaN layer; 203 . . . n-type GaN layer; 204 . . . n-type AlGaN layer; 400 . . . n-type nitride semiconductor layer; 401 . . . n-type GaN layer; and 402 . . . n-type AlGaN layer

### BEST MODE FOR CARRYING OUT THE PRESENT INVENTION

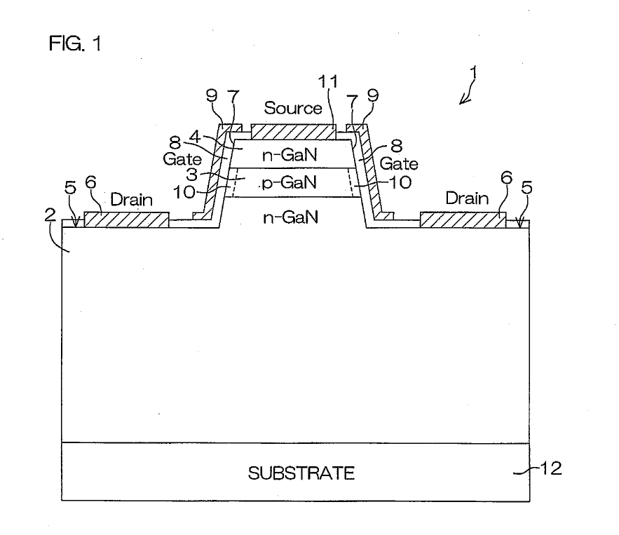

FIG. 1 is a diagrammatic cross-sectional view for describing the structure of a field effect transistor according to a first embodiment of the present invention.

The field effect transistor (nitride semiconductor device) includes a substrate 12, and a nitride semiconductor laminated structure 1 made of GaN compound semiconductor layers grown on the substrate 12.

For the substrate 12, an insulative substrate such as a sapphire substrate, or an electrically conductive substrate such as a GaN substrate, a ZnO substrate, an Si substrate, a GaAs substrate, and an SiC substrate, may be applied, for example.

The nitride semiconductor laminated structure 1 includes an n-type GaN layer 2 (first layer); a p-type GaN layer 3 (second layer); and an n-type GaN layer 4 (third layer). Each GaN layer is laminated in this order.

The nitride semiconductor laminated structure 1, in order to acquire a trapezoid sectional shape (mesa shape), is etched in a direction transversing a lamination interface to a depth at which the n-type GaN layer 2 is exposed from the n-type GaN layer 4. Then, the n-type GaN layer 2 has a drawn section 5 drawn, from both sides of the nitride semiconductor laminated structure 1, in a lateral direction along the lamination interface of the nitride semiconductor laminated structure 1 (Hereinafter, this direction is referred to as a “width direction.”). A drain electrode 6 is formed to come into contact with the surface of the drawn section 5. That is, in the first embodiment, the drawn section 5 drawn from the nitride semiconductor laminated structure 1 in the width direction is configured by an extended section of the n-type GaN layer 2.

On the other hand, near the center in the width direction of the nitride semiconductor laminated structure 1, along with the formation of the drawn section 5, a wall surface 7 across the n-type GaN layer 2, the p-type GaN layer 3, and the n-type GaN layer 4 is formed.

A region 10 near the wall surface 7 in the p-type GaN layer 3 is made of a semiconductor having conductive characteristics different from those of the p-type GaN layer 3, for example, a p-type semiconductor having an acceptor concentration lower than an acceptor concentration of the p-type GaN layer 3. Also, a thickness of the region 10 in a direction orthogonal to the wall surface 7 is several nm to 100 nm, for example. The region 10 is not limited to the p-type semiconductor as long as the semiconductor has conductive characteristics different from those of the p type GaN layer 3, and for example, may be made of an n-type semiconductor containing an n-type impurity, an i-type semiconductor scarcely containing an impurity, or a semiconductor containing both an n-type and p-type impurity. Near the surface of the region 10, there is formed an inversion layer that provides electrical conduction between the n-type GaN layers 2 and 4 when an appropriate bias voltage is applied to a gate electrode 9.

On the n-type GaN layer 4, a source electrode 11 is formed. As a result, the source electrode 11 is electrically connected to the n-type GaN layer 4.

Further, a gate insulating film 8 is formed so as to contact a region other than a region where the drain electrode 6 is formed on the top surface of the n-type GaN layer 2 and a region other than a region where the source electrode 11 (described later) is formed on the top surface of the n-type GaN layer 4. Further, on the gate insulating film 8, the gate electrode 9 is formed so as to oppose the region 10 in a manner crossing the gate insulating film 8. More specifically, the gate electrode 9 is formed so as to oppose the n-type GaN layer 2 and the n-type GaN layer 4, on the wall surface 7, in a manner crossing the gate insulating film 8.

The nitride semiconductor laminated structure 1 is formed on the substrate 12 by a so-called MOCVD growth (Metal Oxide Chemical Vapor Deposition growth), for example.

For example, when the substrate 12 of which the main surface is a c-plane (0001) is used, the nitride semiconductor laminated structure 1 grown on the substrate 12 by epitaxial growth, that is, the n-type GaN layer 2, the p-type GaN layer 3, and the n-type GaN layer 4, are laminated so that the c-plane (0001) is the main surface. Moreover, the plane orientation of the wall surface 7 of the nitride semiconductor laminated structure 1 having a trapezoid sectional shape (mesa shape), for example, is a plane (plane other than the c-plane) inclined in a range of 15 to 90 degrees relative to the c-plane (0001). More specifically, examples thereof include a non-polar plane such as an m-plane (10-10) or an a-plane (11-20), and a semi-polar plane such as (10-13), (10-11), and (11-22).

The gate insulating film 8 can be configured by using an oxide or a nitride, for example. More specifically, the gate insulating film 8 can be configured by using a silicon oxide (SiO₂), a gallium oxide (Ga₂O₃), a magnesium oxide (MgO), a scandium oxide (Sc₂O₃), a silicon nitride (SiN), etc. In particular, it is preferably configured by using the silicon oxide (SiO₂) or the gallium oxide (Ga₂O₃), or both of these.

For the gate electrode 9, for example, an electrical conductive material such as platinum (Pt), aluminum(Al), a nickel-gold alloy (Ni—Au alloy), a nickel-titanium-gold alloy (Ni—Ti—Au alloy), a palladium-gold alloy (Pd—Au alloy), a palladium-titanium-gold alloy (Pd—Ti—Au alloy), a palladium-platinum-gold alloy (Pd—Pt—Au alloy), and a polysilicon can be applied.

It is preferable to configure the drain electrode 6 by a metal at least containing Al, for example, the drain electrode 6 can be configured by a Ti—Al alloy. Similar to the drain electrode 6, the source electrode 11 is preferably configured by a metal containing Al. For example, the source electrode 11 can be configured by a Ti—Al alloy. When the drain electrode 6 and the source electrode 11 are configured by the metal containing Al, a satisfactory contact with a wiring layer (not shown) can be provided. In addition, the drain electrode 6 and the source electrode 11 may be configured by using Mo or an Mo compound (molybdenum silicide, for example); or Ti or a Ti compound (titanium silicide, for example); or W or a W compound (tungsten silicide, for example).

Subsequently, an operation of the field effect transistor will be described.

Between the source electrode 11 and the drain electrode 6, a bias voltage in which a drain electrode 6 side is positive is applied. Thereby, a p-n junction at an interface between the n-type GaN layer 2 and the p-type GaN layer 3 is applied with a reverse voltage, and as a result, a cutoff status is established between the n-type GaN layer 4 and the n-type GaN layer 2, that is, between the source and the drain. From this status, when a bias voltage not less than a predetermined voltage value (gate threshold value voltage) that is positive relative to the region 10 is applied to the gate electrode 9, electrons are induced near the surface of the region 10, thereby forming an inversion layer. Via this inversion layer, conduction is provided between the n-type GaN layer 2 and the n-type GaN layer 4. This provides conduction between the source and the drain. At this time, the region 10 is made of a p type semiconductor of which the acceptor concentration is lower than that of the p-type GaN layer 3, and thus, the electrons can be induced in the region 10 with a lower gate threshold value voltage. When a p-type impurity concentration of the region 10 is appropriately set, if an appropriate bias is applied to the gate electrode 9, conduction is provided between the source and the drain, and if the bias is not applied to the gate electrode 9, a cutoff status is achieved between the source and the drain. That is, a normally-off operation is realized.

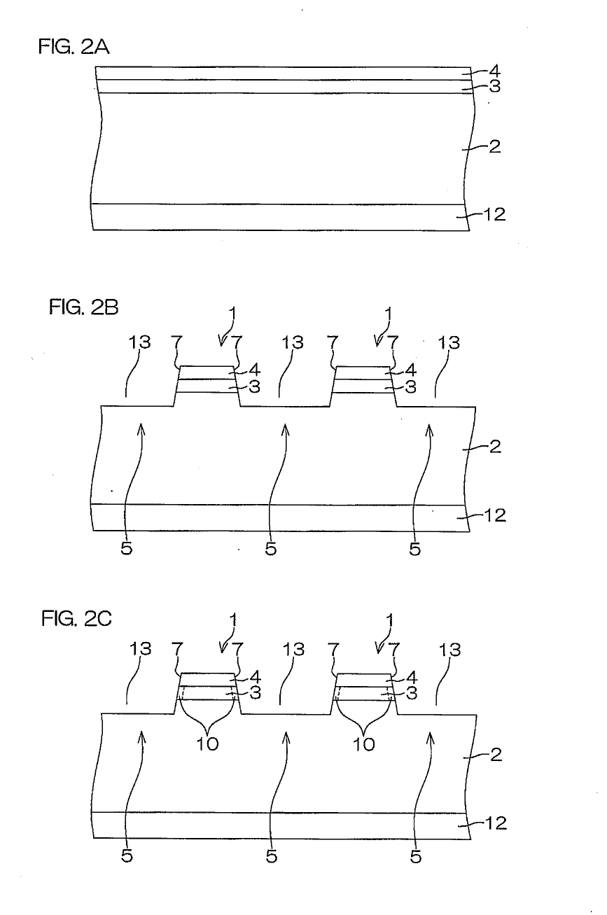

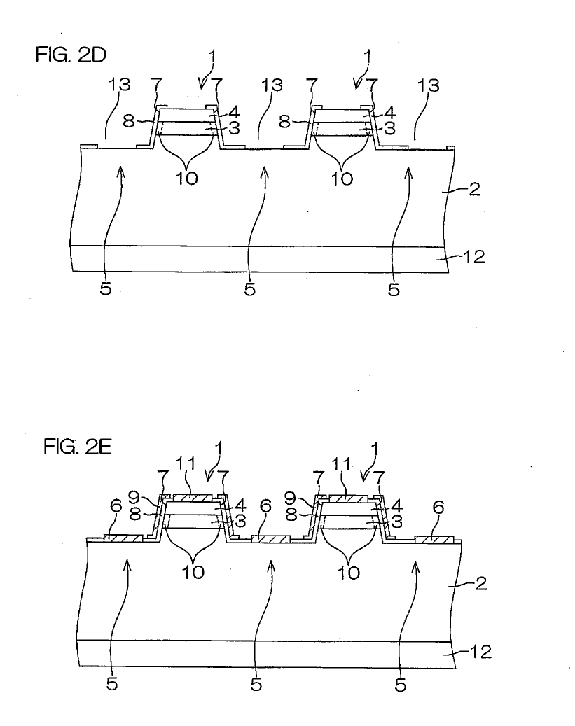

FIG. 2A to FIG. 2E are diagrammatic cross-sectional views each showing a method for manufacturing the field effect transistor in FIG. 1 according to a sequence of steps.

Upon manufacturing this field effect transistor, as shown in FIG. 2A, the n-type GaN layer 2, the p-type GaN layer 3, and the n-type GaN layer 4 are first grown on the substrate 12 in order by an MOCVD growth method, for example. In this way, the nitride semiconductor laminated structure 1 is formed on the substrate 12. Moreover, as an n-type impurity when the n-type GaN layer 2 and the n-type GaN layer 4 are grown, Si may be used, for example. Moreover, as a p-type impurity when the p-type GaN layer 3 is grown, for example, Mg, C, etc., may be used.

After the nitride semiconductor laminated structure 1 is formed, the nitride semiconductor laminated structure 1 is etched in a stripe pattern so that a wall surface 7 having a plane orientation inclined in a range of 15 to 90 degrees relative to the c-plane (0001) is cut out, as shown in FIG. 2B (wall surface forming step). This leads to the formation of a trapezoid sectional (mesa shaped) groove 13 formed from the n-type GaN layer 4 through the p-type GaN layer 3 to the center of a layer thickness of the n-type GaN layer 2. On the substrate 12, a plurality of nitride semiconductor laminated structures 1 (only two of them are shown in FIG. 2B) are neatly shaped in a stripe pattern. Further, the drawn section 5 formed of an extended section of the n-type GaN layer 2, and the wall surface 7 formed of the n-type GaN layer 2, the p-type GaN layer 3, and the n-type GaN layer 4 are simultaneously formed.

The formation of the groove 13 may be performed by dry etching (anisotropic etching) using chlorinated gas, for example. Thereafter, a wet etching process may be further performed, if necessary, to ameliorate the wall surface 7 within the groove 13 that is damaged by the dry etching. Performing of the wet etching process leads to washing of the wall surface 7 of which the damaged surface layer has been removed. Preferably, hydrofluoric acid (HF) or hydrochloric acid (HCl) is used for the wet etching. Thereby, an Si-system oxide, an oxide made of Ga, or any other similar substances are removed, and as a result, a wall surface 7 that is scarcely damaged can be obtained. Reducing the damage of the wall surface 7 enables maintaining a satisfactory crystal status of the region 10 and also leads to the formation of a satisfactory interface between the wall surface 7 and the gate insulating film 8. As a result, an interface level can be reduced. Thereby, a channel resistance can be reduced and also a leak current can be suppressed. Moreover, instead of the wet etching process, a dry etching process during which only low damage occurs may also be applied.

Subsequently, on the nitride semiconductor laminated structure 1, the gate insulating film 8 is formed by an ECR sputtering method, for example. Upon the formation of the gate insulating film 8 by the ECR sputtering method, the substrate 12 formed thereon with the nitride semiconductor laminated structure 1 is first put in an ECR (Electron Cyclotron Resonance) deposition apparatus, and is irradiated with an Ar⁺ plasma having energy of approximately 30 eV for several seconds, for example. Irradiation of the Ar⁺ plasma transforms a region near the wall surface 7 in the p-type GaN layer 3, as shown in FIG. 2C, thereby leading to the formation of the region 10 of a p⁻ type semiconductor that has conductive characteristics different from those of the p-type GaN layer 3, for example, a lower acceptor concentration than the p-type GaN layer 3 (a fourth-layer forming step).

Subsequently, a insulating film (silicon oxide, gallium oxide, etc.) that covers the entire surface of the nitride semiconductor laminated structure 1 is formed. Then, after the formation of the insulating film, as shown in FIG. 2D, an unnecessary portion of the insulating film (a portion other than the gate insulating film 8) is removed by etching, and thereby, the gate insulating film 8 is formed (a gate insulating film forming step).

Thereafter, according to a well-known photolithography technique, the gate insulating film 8 is formed thereon with a photoresist (not shown) having an opening in a region where the gate electrode 9, the drain electrode 6, and the source electrode 11 should be formed, and a metal (platinum, aluminum, etc, for example) used for materials of these electrodes (9, 6, and 11) is formed by a sputtering method or any other similar method. Subsequently, when the photoresist is removed, an unnecessary portion of the metal (a portion other than the electrodes (9, 6, and 11)) is lifted off together with the photoresist. Thereby, as shown in FIG. 2E, the gate electrode 9 that opposes the region 10 is formed in a manner crossing the gate insulating film 8, and also, the drain electrode 6 is formed so as to come into contact with the top surface of the drawn section 5 (extended section of the n-type GaN layer 2) and the source electrode 11 is formed so as to come into contact with the top surface of the n-type GaN layer 4.

As described above, the field effect transistor of the structure shown in FIG. 1 can be obtained.

Moreover, the gate insulating film 8 is formed by the ECR sputtering method. However, the method of forming the gate insulating film 8 includes, not limited to the ECR sputtering method, a method of forming it by a magnetron sputtering method, for example. Further, depending on a forming method and a forming condition of the gate insulating film 8, oxygen which is an n-type impurity, for example, is ion implanted on the wall surface 7 in the p-type GaN layer 3 upon the formation of the gate insulating film 8. Thus, also at the time of the formation of the gate insulating film 8, a region near the wall surface 7 in the p-type GaN layer 3 is transformed. That is, a step of forming the region 10 and a step of forming the gate insulating film 8 are simultaneously performed in parallel.

In addition to the step of forming the gate insulating film 8, a step of irradiating a region on the wall surface 7 in the p-type GaN layer 3 with plasma or an electron beam, or a step of ion implanting the region on the wall surface 7 in the p-type GaN layer 3 may be further arranged. Through these steps, the region near the wall surface 7 in the p-type GaN layer 3 is transformed, and thereby, the region 10 made of an n-type semiconductor can be formed.

Also, the nitride semiconductor laminated structure 1 may suffice to include at least an n-type Group III nitride semiconductor layer, a Group III nitride semiconductor layer, of conductive characteristics, containing a p-type impurity, and an n-type Group III nitride semiconductor layer, and may be configured to be formed so that in addition to the n-type GaN layer 2, the p-type GaN layer 3, and the n-type GaN layer 4, an i-type GaN layer, etc., come into contact with the substrate 12 and the n-type GaN layer 2.

In addition, as an epitaxial growth method for forming the nitride semiconductor laminated structure 1, any one of the following methods of: a liquid phase epitaxial growth, a vapor phase epitaxial growth, and a molecular beam epitaxial (MBE) growth, may be applied.

Also, in FIG. 1, the region 10 is shown only on the wall surface 7 in the p-type GaN layer 3. In reality, however, the transformed region is formed also on the wall surface 7 in the n-type GaN layer 2 or the n-type GaN layer 4. It should be noted that even when the transformed region is formed on the wall surface 7 in the n-type GaN layer 2 or the n-type GaN layer 4, there is no change in a device effect, and therefore, the transformed region is omitted in FIG. 1.

Further, the plurality of nitride semiconductor laminated structures 1 formed in a stripe pattern on the substrate 12 each form a unit cell. The gate electrodes 9, the drain electrodes 6, and the source electrode 11 of the plurality of nitride semiconductor laminated structures 1 are commonly connected to each other at a position not shown. The drain electrode 6 may be shared between the adjacent nitride semiconductor laminated structures 1.

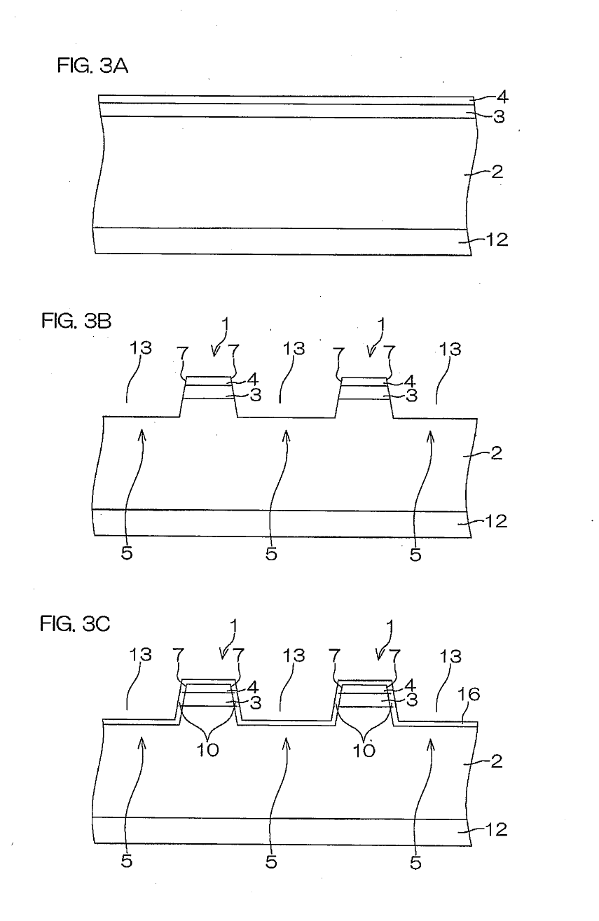

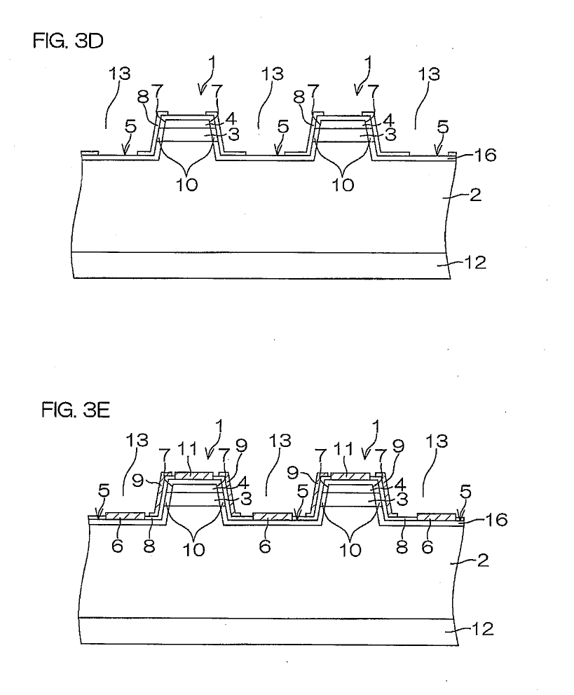

FIG. 3A to FIG. 3E are diagrammatic cross-sectional views each showing another method for manufacturing the field effect transistor in FIG. 1 according to a sequence of steps.

Upon manufacturing by this manufacturing method, the n-type GaN layer 2, the p-type GaN layer 3, and the n-type GaN layer 4 are first grown on the substrate 12 in order by an MOCVD growth method, as shown in FIG. 3A, for example. In this way, the nitride semiconductor laminated structure 1 is formed on the substrate 12.

After the nitride semiconductor laminated structure 1 is formed, the nitride semiconductor laminated structure 1 is etched in a stripe pattern so that the wall surface 7 having a plane orientation inclined in a range of 15 to 90 degrees relative to the c-plane (0001) is cut out, as shown in FIG. 3B (wall surface forming step). This simultaneously forms: the trapezoid sectional (mesa shaped) groove 13 formed from the n-type GaN layer 4 through the p-type GaN layer 3 to the middle of a layer thickness of the n-type GaN layer 2; and the wall surface 7 made of the n-type GaN layer 2, the p-type GaN layer 3, and the n-type GaN layer 4. The method of forming the groove 13 is similar to that in the above-described manufacturing method.

Next, as shown in FIG. 3C, from the surfaces of the n-type GaN layer 2, the p-type GaN layer 3, and the n-type GaN layer 4, an n-type GaN layer 16 is epitaxially grown, for example (fourth layer forming step).

More specifically, under a condition that favors the growth of the n-type GaN layer 16 (a growth temperature, a pressure inside a chamber, etc.), the crystal of the n-type GaN layer 16 is grown by using, as a core, the n-type GaN layer 2, the p-type GaN layer 3, and the n-type GaN layer 4. Thereby, from each of the surfaces of the n-type GaN layer 2, the p-type GaN layer 3, and the n-type GaN layer 4, the n-type GaN layer 16 extended along the surfaces of these layers is grown. In the n-type GaN layer 16, a portion that contacts the wall surface 7 in the p-type GaN layer 3 results in the region 10, made of an n-type semiconductor, for example, different in conductive characteristic from the p-type GaN layer 3. In FIG. 3C to FIG. 3E, for the sake of convenience, the region 10 on the n-type GaN layer 16 is shown by a dotted line. As the n-type impurity used when the n-type GaN layer 16 is epitaxially grown, the same impurity as those in the n-type GaN layer 2 and the n-type GaN layer 4, for example, Si, may be used.

Subsequently, as shown in FIG. 3D, on the nitride semiconductor laminated structure 1, the gate insulating film 8 is formed by, for example, an ECR sputtering method, the gate electrode 9 that opposes the region 10 is formed in a manner crossing the gate insulating film 8, as shown in FIG. 3E, and also, the drain electrode 6 is formed so as to come into contact with the top surface of the drawn section 5 (extended section of the n-type GaN layer 2) or the source electrode 11 is formed so as to come into contact with the top surface of the n-type GaN layer 4.

In this way, the field effect transistor substantially equivalent to that of the structure shown in FIG. 1 can be obtained.

As described above, according to the first embodiment, when the structure in which the gate insulating film 8 is formed so as to contact the region 10 formed on the surface exposed to the wall surface 7 in the p-type GaN layer 3 is adopted, a gate voltage value necessary for the formation of the inversion layer can be decreased. As a result, while the acceptor concentration of the p-type GaN layer 3 is kept high so that no reach-through breakdown occurs, the gate threshold value voltage can be lowered, and a satisfactory transistor operation can be performed, thereby realizing a satisfactory power device.

Moreover, by controlling the impurity concentration and the film thickness of the region 10, the normally-off operation is enabled, and because of a vertical transistor structure in which the n-type GaN layer 2, the p-type GaN layer 3, and the n-type GaN layer 4 are laminated, a large amount of current can flow and a high withstand voltage field effect transistor can be also realized.

Also, the gate electrode 9 is formed so as to oppose the n-type GaN layer 2 and the n-type GaN layer 4, on the wall surface 7, in a manner crossing the gate insulating film 8, and thus, the MIS structure can be configured to the depletion layer expanding to the n-type GaN layer 2 and the n-type GaN layer 4 above and beneath the region 10. As a result, upon the formation of a channel in the region 10, an accumulation layer is formed also in the depletion layer expanded to the n-type GaN layer 2 and the n-type GaN layer 4, and thus, during an on time, a current can pass without interference by the depletion layer. As a result, an ON resistance can be further reduced.

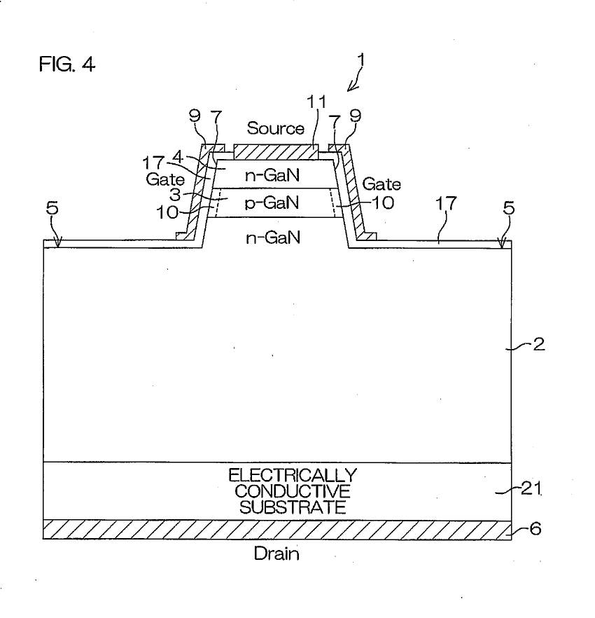

FIG. 4 is a diagrammatic cross-sectional view for describing the structure of a field effect transistor according to a second embodiment of the present invention. In FIG. 4, portions corresponding to those in the preceding FIG. 1 are shown with the same reference numerals as those in FIG. 1.

In the second embodiment, instead of the substrate 12 shown in FIG. 1, an electrically conductive substrate 21 is applied.

Then, on one surface of the electrically conductive substrate 21, the nitride semiconductor laminated structure 1 is placed. On the other hand, on the other surface of the electrically conductive substrate 21, the drain electrode 6 is formed so as to come into contact with the electrically conductive substrate 21 in a manner to cover the entire region of the other surface. Therefore, in the second embodiment, the drain electrode 6 is electrically connected via the electrically conductive substrate 21 to the n-type GaN layer 2.

Also, the nitride semiconductor laminated structure 1 is formed with a gate insulating film 17 so that the wall surface 7 formed in the nitride semiconductor laminated structure 1 is covered and further a region other than a region where the source electrode 11 is formed on the top surface of the n-type GaN layer 4 is covered. Further, on the gate insulating film 17, the gate electrode 9 is formed so as to oppose the p-type GaN layer 3 in a manner crossing the gate insulating film 17. The rest of the configuration is similar to that in the case of the preceding first embodiment.

The electrically conductive substrate 21 comes into contact with the n-type GaN layer 2 over the entire surface region, and thus, electrons supplied through the region 10 to the n-type GaN layer 2 are headed for the electrically conductive substrate 21 through a wide range of this n-type GaN layer 2, and flown into the drain electrode 6 via this electrically conductive substrate 21. In this way, a current concentration can be suppressed.

Also, according to this configuration, an operation similar to that in the first embodiment is possible, and an effect similar to that in the first embodiment can be obtained.

As the electrically conductive substrate 21, a GaN substrate, a ZnO substrate, an Si substrate, a GaAs substrate, an SiC substrate, etc., can be applied. In particular, it is preferable to use the GaN substrate. When the GaN substrate is used as the electrically conductive substrate 21, the lattice constant thereof can be matched to that of the n-type GaN layer 2 formed on the surface of the electrically conductive substrate 21. Therefore, when the GaN substrate is used as the electrically conductive substrate 21 and the n-type GaN layer 2, the p-type GaN layer 3, and the n-type GaN layer 4 are epitaxially grown in order on the surface of the electrically conductive substrate 21, the nitride semiconductor laminated structure 1 having only a small amount of lattice defects can be obtained.

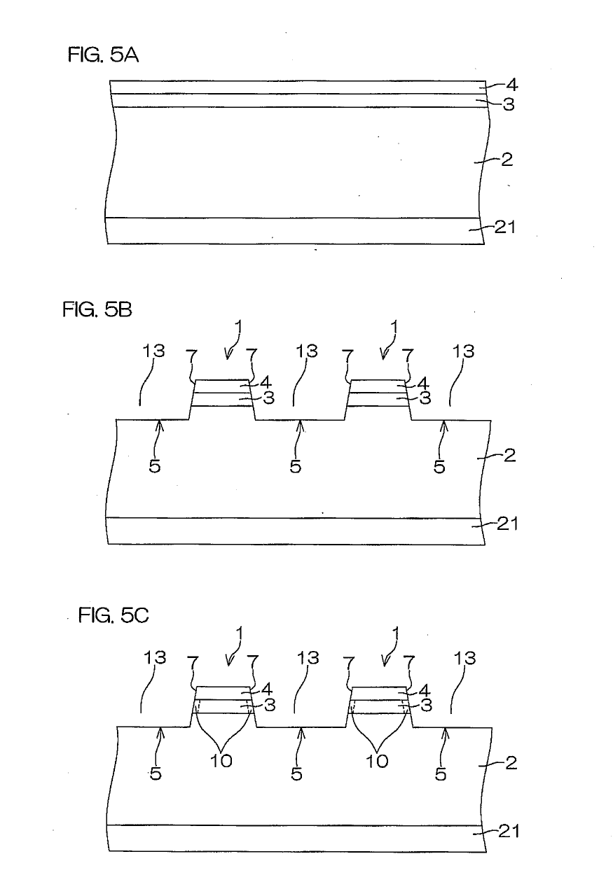

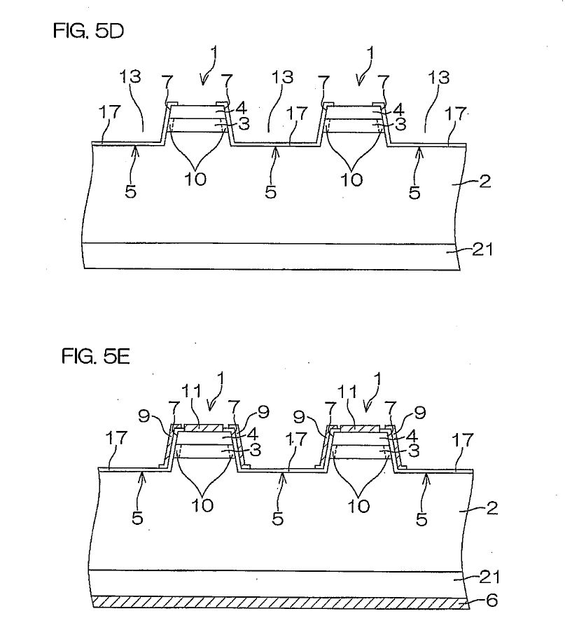

FIG. 5A to FIG. 5E are diagrammatic cross-sectional views each showing a method for manufacturing the field effect transistor in FIG. 4 according to a sequence of steps.

Upon manufacturing this field effect transistor, as shown in FIG. 5A, the n-type GaN layer 2, the p-type GaN layer 3, and the n-type GaN layer 4 are first grown on the electrically conductive substrate 21 in order by an MOCVD growth method, for example. In this way, the nitride semiconductor laminated structure 1 is formed on the electrically conductive substrate 21.

After the nitride semiconductor laminated structure 1 is formed, the nitride semiconductor laminated structure 1 is etched in a stripe pattern so that the wall surface 7 having a plane orientation inclined in a range of 15 to 90 degrees relative to the c-plane (0001) is cut out, as shown in FIG. 5B (wall surface forming step). Thereby, the rectangle sectional groove 13 is formed from the n-type GaN layer 4 through the p-type GaN layer 3 to the middle of a layer thickness of the n-type GaN layer 2. On the electrically conductive substrate 21, a plurality of nitride semiconductor laminated structures 1 (only two of them are shown in FIG. 5B) are neatly shaped in a stripe pattern. Further, the drawn section 5 formed of an extended section of the n-type GaN layer 2, and the wall surface 7 formed of the n-type GaN layer 2, the p-type GaN layer 3, and the n-type GaN layer 4 are simultaneously formed. In addition, the method of forming the groove 13 is similar to that of the first embodiment.

Subsequently, on the nitride semiconductor laminated structure 1, the gate insulating film 17 is formed by an ECR sputtering method, for example. Also, a method of forming the gate insulating film 17 is similar to that of the gate insulating film 8 in the first embodiment. That is, upon the formation of the gate insulating film 17, when an Ar⁺ plasma is first irradiated, a region near the wall surface 7 in the p-type GaN layer 3 is transformed, as shown in FIG. 5C, thereby leading to the formation of the region 10 of the p⁻ type semiconductor that has conductive characteristics different from those of the p-type GaN layer 3, for example, a lower acceptor concentration than the p-type GaN layer 3 (a fourth layer forming step). Thereafter, as shown in FIG. 5D, the gate insulating film 17 is formed (gate insulating film forming step).

Next, as shown in FIG. 5E, the gate electrode 9 and the source electrode 11 are formed by the forming method similar to the case in the first embodiment. Also, the drain electrode 6 is formed so as to come into contact with the bottom surface of the electrically conductive substrate 21.

As described above, the field effect transistor of the structure shown in FIG. 4 can be obtained.

In addition, the plurality of nitride semiconductor laminated structures 1 formed in a stripe pattern on the electrically conductive substrate 21 each form a unit cell. The gate electrodes 9 and the source electrodes 11 of the plurality of nitride semiconductor laminated structures 1 are commonly connected to each other at a position not shown. The drain electrode 6 is formed to come into contact with the electrically conductive substrate 21, and serves as an electrode common to all the cells.

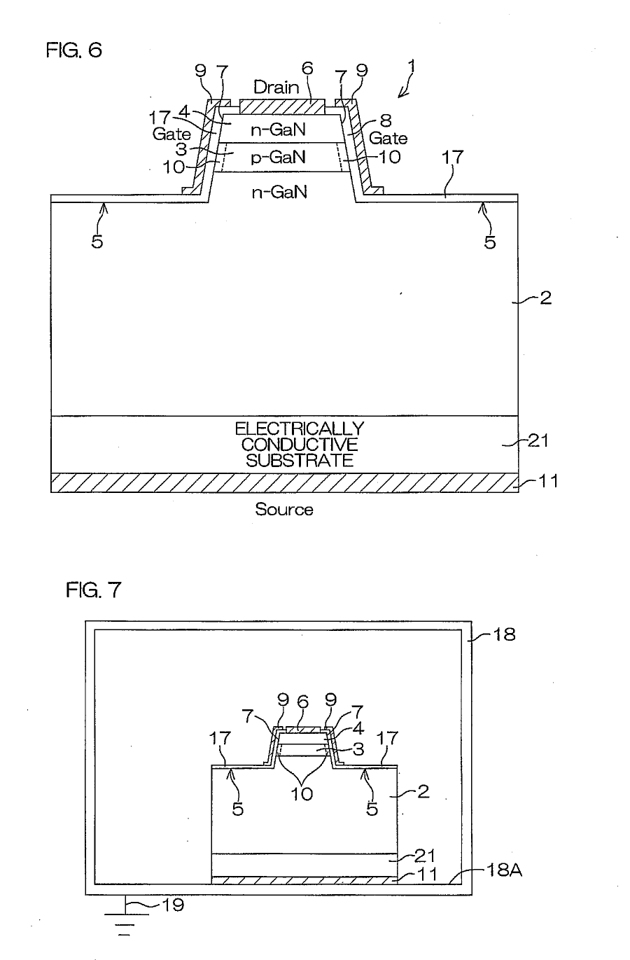

Also, in the second embodiment, as shown in FIG. 6, instead of the source electrode 11, the drain electrode 6 is formed on the top surface of the n-type GaN layer 4, and instead of the drain electrode 6, the source electrode 11 is formed so as to come into contact with the electrically conductive substrate 21. In this way, it becomes possible to adopt a structure in which a position at which the drain electrode 6 is placed and that at which the source electrode 11 is placed are switched.

When the field effect transistor having such a structure is mounted on a substantially cuboid, hollow package housing 18, made of an electrically conductive material, as shown in FIG. 7, a nitride semiconductor package according to one embodiment of the present invention can be obtained.

In this nitride semiconductor package, the field effect transistor is mounted so that inside the package housing 18, the source electrode 11 is loaded so as to come into contact with an inner bottom surface 18A of the package housing 18 or the drain electrode 6 is loaded so as to be connected to an external electrode not shown. Thereby, when the package housing 18 is grounded by a grounding line 19, the source electrode 11 can be grounded via the package housing 18. That is, it is not necessary to arrange a ground wire for connecting the source electrode 11 and the package housing 18 in order to ground the source electrode 11, and thus, the structure of the package can be simplified. Further, when the package thus simplified is used, its assembly is easily performed as well.

In this nitride semiconductor package, it is preferable to adopt the GaN substrate as the electrically conductive substrate 21. The GaN substrate has a high heat conductivity, and thus, the heat generated in the drain electrode 6 can be effectively transmitted to the package housing 18 via the n-type GaN layer 4, the p-type GaN layer 3, the n-type GaN layer 2, the electrically conductive substrate 21, and the source electrode 11, and that heat can be dissipated from the package housing 18.

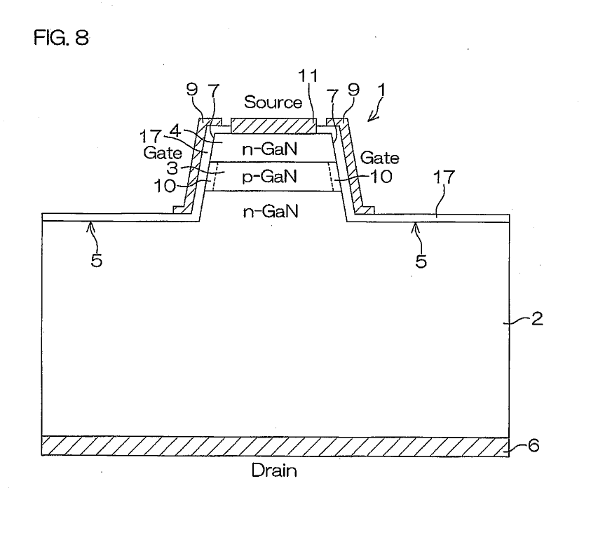

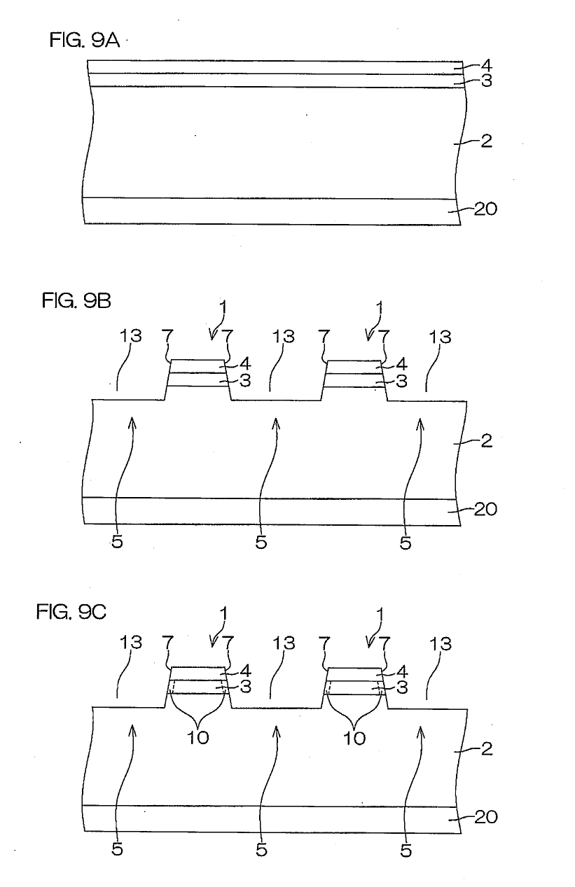

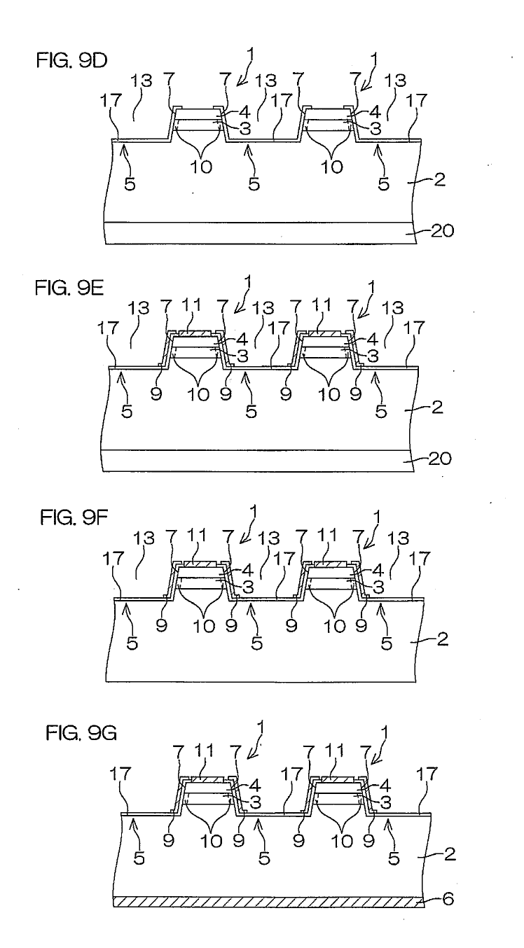

FIG. 8 is a diagrammatic cross-sectional view for describing the structure of a field effect transistor according to a third embodiment of the present invention. In FIG. 8, portions corresponding to those in the preceding FIG. 1 and FIG. 4 are shown with the same reference numerals as those in FIG. 1.

In the third embodiment, a substrate 20 (described later) used for growing the nitride semiconductor laminated structure 1 is removed, and in the nitride semiconductor laminated structure 1, the drain electrode 6 is formed to come into contact with the surface opposite to the gate electrode 9. More specifically, the drain electrode 6 is deposited and formed to cover a substantially entire region of the bottom surface of the n-type GaN layer 2. Therefore, in the field effect transistor, a field effect transistor having a vertical structure can be realized even when an insulative substrate is used for the crystal growth, and further, because the insulative substrate is removed, a resistance of the substrate when the transistor is operated can be diminished. Also, electrons flown into the n-type GaN layer 2 are diffused and flown in a wide range of the n-type GaN layer 2, and flown into the drain electrode 6. Therefore, concentration of currents can be suppressed. The rest of the configuration is similar to that in the case of the preceding first and second embodiments.

FIG. 9A to FIG. 9G are diagrammatic cross-sectional views each showing a method for manufacturing the field effect transistor in FIG. 8 according to a sequence of steps.

Upon manufacturing this field effect transistor, as shown in FIG. 9A, the n-type GaN layer 2, the p-type GaN layer 3, and the n-type GaN layer 4 are first grown on the substrate 20 in order by an MOCVD growth method, for example. In this way, the nitride semiconductor laminated structure 1 is formed on the substrate 20.

As the substrate 20, a sapphire substrate, a ZnO substrate, an Si substrate, a GaAs substrate, a GaN substrate, or an SiC substrate can be applied. In particular, it is most preferable to use the GaN substrate in view of matching the lattice constant to that of each Group III nitride semiconductor layer (2, 3, and 4). In addition, the following is also preferable: on the sapphire substrate, a GaN epitaxial growth layer (not shown) is formed by a lateral direction selective epitaxial growth, for example, and by using this as the substrate 20, the n-type GaN layer 2, the p-type GaN layer 3, and the n-type GaN layer 4 are epitaxially grown in order on the GaN epitaxial growth layer.

After the nitride semiconductor laminated structure 1 is formed, the nitride semiconductor laminated structure 1 is etched in a stripe pattern so that the wall surface 7 having a plane orientation inclined in a range of 15 to 90 degrees relative to the c-plane (0001) is cut out, as shown in FIG. 9B (wall surface forming step). Thereby, the rectangle sectional groove 13 is formed from the n-type GaN layer 4 through the p-type GaN layer 3 to the middle of a layer thickness of the n-type GaN layer 2. On the substrate 12, a plurality of nitride semiconductor laminated structures 1 (only two of them are shown in FIG. 9B) are neatly shaped in a stripe pattern. Further, the drawn section 5 formed of an extended section of the n-type GaN layer 2, and the wall surface 7 formed of the n-type GaN layer 2, the p-type GaN layer 3, and the n-type GaN layer 4 are simultaneously formed. In addition, the method of forming the groove 13 is similar to that of the first embodiment.

Subsequently, on the nitride semiconductor laminated structure 1, the gate insulating film 17 is formed by an ECR sputtering method, for example. Also, a method of forming the gate insulating film 17 is similar to that of the gate insulating film 8 in the first embodiment. That is, upon the formation of the gate insulating film 17, when an Ar⁺ plasma is first irradiated, a region near the wall surface 7 in the p-type GaN layer 3 is transformed, as shown in FIG. 9C, thereby leading to the formation of the region 10 of the p⁻ type semiconductor that has conductive characteristics different from those of the p-type GaN layer 3, for example, a lower acceptor concentration than the p-type GaN layer 3. Thereafter, as shown in FIG. 9D, the gate insulating film 17 is formed (gate insulating film forming step).

Next, as shown in FIG. 9E, the gate electrode 9 and the source electrode 11 are formed by the forming method similar to the case in the first embodiment.

After the formation of the gate electrode 9 and the source electrode 11, the substrate 20 is removed, as shown in FIG. 9F. The substrate 20 can be removed by a laser lift off method in which a laser beam is strikes from the plane of the substrate 20 to separate the substrate 20, a CMP (Chemical Mechanical Polishing) process, and an etching process.

Thereafter, as shown in FIG. 9G, the drain electrode 6 is formed. In this case, the drain electrode 6 is formed to come into contact with the n-type GaN layer 2.

As described above, the field effect transistor of the structure shown in FIG. 8 can be obtained.

The plurality of nitride semiconductor laminated structures 1 formed in a stripe pattern each form a unit cell. The gate electrodes and the source electrodes 11 of the plurality of nitride semiconductor laminated structures 1 are commonly connected to each other at a position not shown. The drain electrode 6 is formed to come into contact with the n-type GaN layer 2, and serves as an electrode common to all the cells.

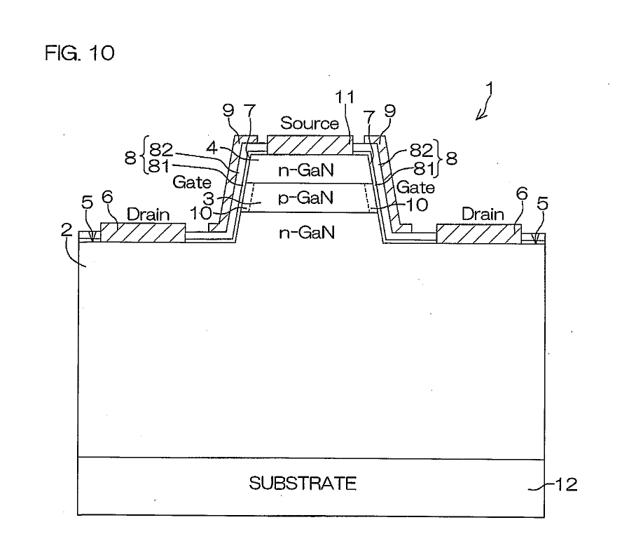

FIG. 10 is a diagrammatic cross-sectional view for describing the structure of a field effect transistor according to a fourth embodiment of the present invention. In FIG. 10, portions corresponding to those shown in the preceding FIG. 1 are shown with the same reference numerals.

In the fourth embodiment, the gate insulating film 8 is formed of a combination of a silicon nitride and a silicon oxide. More specifically, the gate insulating film 8 covers the entire region of the surface of the nitride semiconductor laminated structure 1, and is configured by a silicon nitride film 81 formed on the surface of the nitride semiconductor laminated structure 1 and a silicon oxide film 82 formed on the silicon nitride film 81. That is, the silicon nitride film 81 is formed to come into contact with the wall surface 7.

Preferably, the film thickness of the silicon nitride film 81 is 1 Å to 100 Å, for example, and more preferably, the film thickness thereof is approximately 10 Å. On the other hand, preferably, the film thickness of the silicon oxide film 82 is 100 Å to 3000 Å, and more preferably, for example, the film thickness thereof is approximately 1000 Å to 2000 Å. The rest of the configuration is similar to that in the first embodiment, and the operation thereof is also similar thereto.

A insulating film that contacts the wall surface 7 is the silicon nitride film 81, and thus, an interface charge on the wall surface 7 can be suppressed and an off leak current can be reduced. Also, when the gate insulating film 8 is configured solely by a nitride (silicon nitride film 81), the withstand voltage is low. However, when the gate insulating film 8 is configured to contain a nitride (silicon nitride film 81) and an oxide (silicon oxide film 82), the withstand voltage can be improved. As a result, the transistor operation can be improved. Moreover, as needed, a silicon oxynitride (SiON) may be used. The silicon oxynitride may be formed by mixing oxygen into a silicon nitride or formed by mixing nitride into a silicon oxide.

Also, according to this configuration, an operation similar to that in the first embodiment is possible, and an effect similar to that in the first embodiment can be obtained.

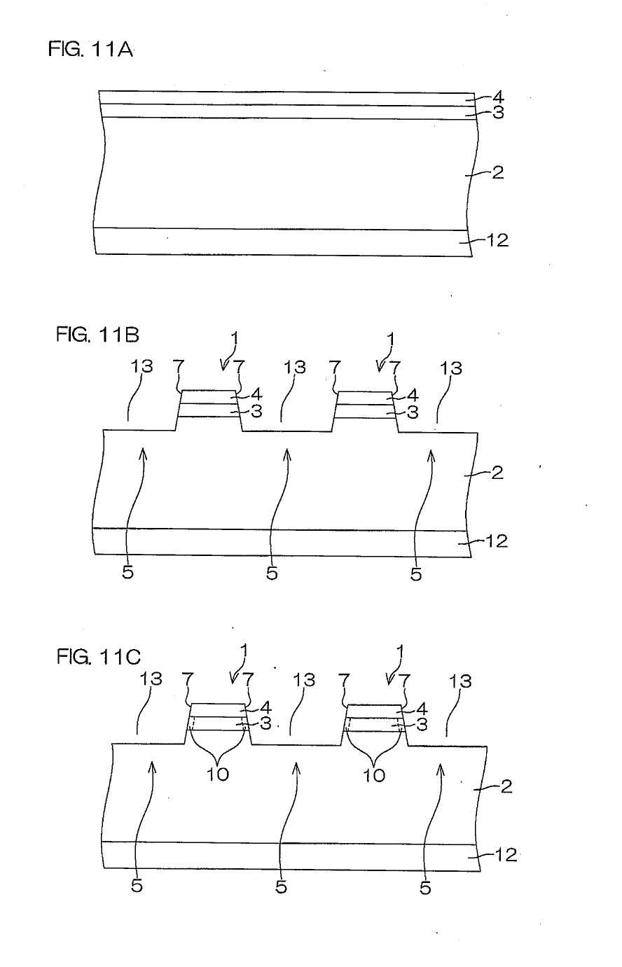

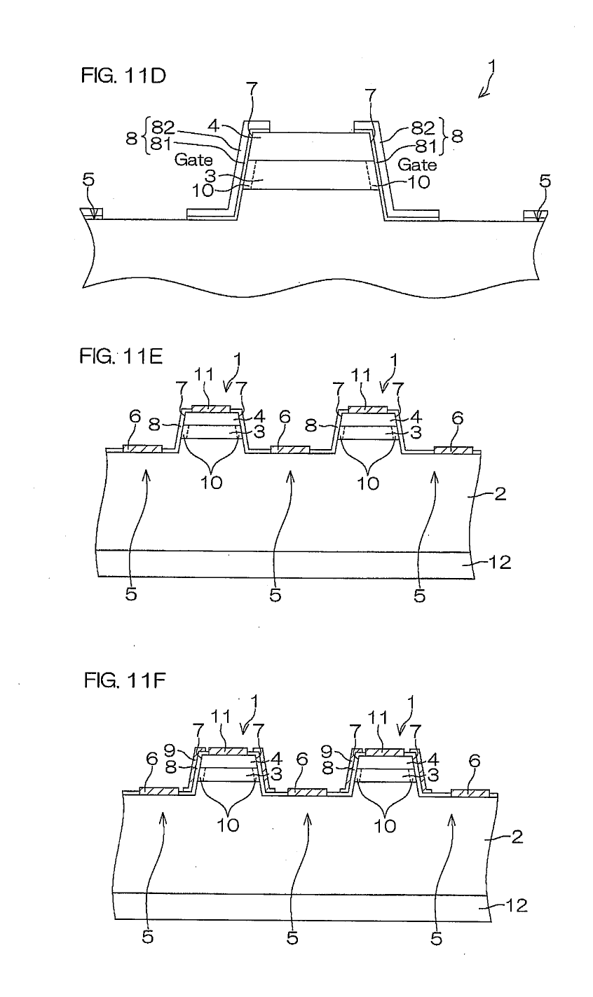

FIG. 11A to FIG. 11F are diagrammatic cross-sectional views each showing a method for manufacturing the field effect transistor in FIG. 10 according to a sequence of steps.

Upon manufacturing this field effect transistor, as shown in FIG. 11A, the n-type GaN layer 2, the p-type GaN layer 3, and the n-type GaN layer 4 are first grown on the substrate 12 in order by an MOCVD growth method, for example. In this way, the nitride semiconductor laminated structure 1 is formed on the substrate 12.

After the nitride semiconductor laminated structure 1 is formed, the nitride semiconductor laminated structure 1 is etched in a stripe pattern so that the wall surface 7 having a plane orientation inclined in a range of 15 to 90 degrees relative to the c-plane (0001) is cut out, as shown in FIG. 11B (wall surface forming step). Thereby, the rectangle sectional groove 13 is formed from the n-type GaN layer 4 through the p-type GaN layer 3 to the middle of a layer thickness of the n-type GaN layer 2. On the substrate 12, a plurality of nitride semiconductor laminated structures 1 (only two of them are shown in FIG. 11B) are neatly shaped in a stripe pattern. Further, the drawn section 5 formed of an extended section of the n-type GaN layer 2, and the wall surface 7 formed of the n-type GaN layer 2, the p-type GaN layer 3, and the n-type GaN layer 4 are simultaneously formed. Also, the method of forming the groove 13 is similar to that of the first embodiment.

Subsequently, on the nitride semiconductor laminated structure 1, the gate insulating film 8 is formed by an ECR sputtering method, for example. Upon the formation of the gate insulating film 8 by the ECR sputtering method, the substrate 12 formed thereon with the nitride semiconductor laminated structure 1 is first put in an ECR deposition apparatus, and is irradiated with an Ar⁺ plasma having energy of approximately 30 eV for several seconds, for example. Irradiation of the Ar⁺ plasma transforms a region near the wall surface 7 in the p-type GaN layer 3, as shown in FIG. 11C, thereby leading to the formation of the region 10 of a p⁻ type semiconductor that has conductive characteristics different from those of the p-type GaN layer 3, for example, a lower acceptor concentration than the p-type GaN layer 3 (a fourth-layer forming step).

Thereafter, the silicon nitride film 81 that covers the entire surface of the nitride semiconductor laminated structure 1 is formed. At this time, a film deposition amount of the silicon nitride is controlled so that the film thickness of the silicon nitride film 81 reaches the above-described film thickness. Then, after the formation of the silicon nitride film 81, the silicon oxide film 82 that covers the entire surface of the silicon nitride film 81 is formed. In this way, the gate insulating film 8 formed of a laminated structure of the silicon nitride film 81 and the silicon oxide film 82 is formed. Thereafter, an unnecessary portion (portion where the electrodes (6, 11) are formed) of the gate insulating film 8 is removed by etching, and as a result, the configuration shown in FIG. 11D is achieved.

Next, as shown in FIG. 11E, according to a well-known photolithography technique, a photoresist (not shown) having an opening is formed in a region where the drain electrode 6 and the source electrode 11 should be formed, and a metal (platinum, aluminum, etc, for example) used for materials of these electrodes (6 and 11) is formed by a sputtering method or any other similar method. Subsequently, the photoresist is removed, and thereby, an unnecessary portion of the metal (a portion other than the electrodes (6 and 11)) is lifted off together with the photoresist. Thereby, the drain electrode 6 is formed so as to come into contact with the top surface of the drawn section 5 and the source electrode 11 is formed so as to come into contact with the top surface of the n-type GaN layer 4. After the formation of the drain electrode 6 and the source electrode 11, a thermal alloying (annealing) is performed.

Then, as shown in FIG. 11F, by a method similar to that of forming the drain electrode 6 and the source electrode 11, the gate electrode 9 that opposes the wall surface 7 is formed in a manner crossing the gate insulating film 8.

Thus, the field effect transistor of the structure shown in FIG. 10 can be obtained.

In addition, the plurality of nitride semiconductor laminated structures 1 formed in a stripe pattern on the substrate 12 each form a unit cell. The gate electrodes 9, the drain electrodes 6, and the source electrodes 11 of the plurality of nitride semiconductor laminated structures 1 are commonly connected to each other at a position not shown. The drain electrode 6 may be shared between the adjacent nitride semiconductor laminated structures 1.

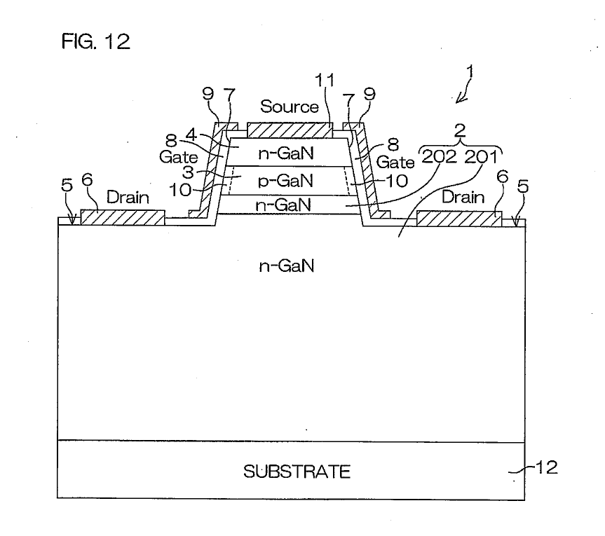

FIG. 12 is a diagrammatic cross-sectional view for describing the structure of a field effect transistor according to a fifth embodiment of the present invention. In FIG. 12, portions corresponding to those shown in the preceding FIG. 1 are shown with the same reference numerals.

In the fifth embodiment, the n-type GaN layer 2 comprises a lower-sided n-type GaN layer 201 (lower layer) laminated on the substrate 12 and an upper-sided n-type GaN layer 202 (upper layer) laminated on the n-type GaN layer 201.

Also, an impurity concentration of the n-type GaN layer 202 (in the fifth embodiment, an n-type impurity concentration) is 10¹⁵ to 10¹⁸ cm⁻³, for example, and an impurity concentration of the n-type GaN layer 201 is 10¹⁷ to 10¹⁹ cm⁻³, for example. That is, the impurity concentration of the n-type GaN layer 202 is smaller than the impurity concentration of the n-type GaN layer 201. The rest of the configuration is similar to that in the above-described first embodiment, and the operation thereof is also similar thereto.

The impurity concentration of the n-type GaN layer 202 is smaller than that of the n-type GaN layer 201, and thus, when the transistor is operated in a saturation region, the depletion layer can be expanded to an n-type GaN layer 202 side. Thus, it is possible to suppress the reach-through breakdown generated when the depletion layer is expanded to the p-type GaN layer 3 side. Also, the impurity concentration of the n-type GaN layer 201 is larger than that of the n-type GaN layer 202, and thus, the ON resistance can be lowered.

Also, according to this configuration, an operation similar to that in the first embodiment is possible, and an effect similar to that in the first embodiment can be obtained.

The field effect transistor can be fabricated according to a method which resembles that described with reference to FIGS. 2A to 2E. That is, the n-type GaN layer 201 and the n-type GaN layer 202 may be epitaxially grown in this order on the substrate 12.

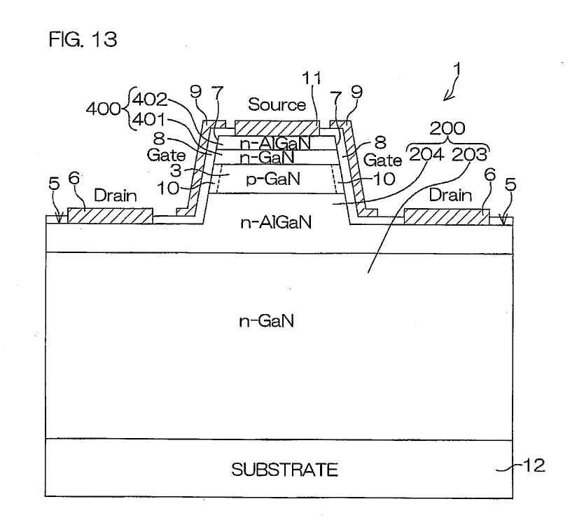

FIG. 13 is a diagrammatic cross-sectional view for describing the structure of a field effect transistor according to a sixth embodiment of the present invention. In FIG. 13, portions corresponding to those shown in the preceding FIG. 1 are shown with the same reference numerals.

In the sixth embodiment, an n-type nitride semiconductor layer 200 comprises an n-type GaN layer 203 (instead of the n-type GaN layer 2 in the preceding embodiment) and an n-type AlGaN layer 204 laminated on this n-type GaN layer 203 is applied. That is, the n-type nitride semiconductor layer 200 is formed of a plurality of (in FIG. 13, two) layers different in composition.

Moreover, an n-type nitride semiconductor layer 400 comprising an n-type GaN layer 401 (instead of the n-type GaN layer 4) and an n-type AlGaN layer 402 laminated on this n-type GaN layer 401 is applied. That is, the n-type nitride semiconductor layer 400 is formed of a plurality of (in FIG. 13, two) layers different in composition.

Then, the drawn section 5 is formed of an extended section of the n-type AlGaN layer 204, and the drain electrode 6 is formed so as to come into contact with the n-type AlGaN layer 204.

The source electrode 11 is formed so as to come into contact with the top surface of the n-type AlGaN layer 402.

Also, each of the n-type AlGaN layers (204 and 402) generally is expressed by AlₓGa_{y}N (0≦x≦1, 0≦y≦1, and 0≦x+y≦1), and for example, it is expressed by Al_{0.2}Ga_{0.8}N. The rest of the configuration is similar to that in the above-described first embodiment, and the operation thereof is also similar thereto.

As described above, when each of the n-type AlGaN layers (204 and 402) is of a composition expressed by Al_{0.2}Ga_{0.8}N, a two-dimensional electron gas (sheet carrier 1×10¹³ cm⁻³; electron mobility 1000 cm²/V·s) is formed near a boundary portion between each of the n-type AlGaN layers (204 and 402) and each of the GaN layers (203 and 401) contacting the same. Thus, the resistance parasitic to the source layer (n-type nitride semiconductor layer 400) and the drain layer (n-type nitride semiconductor layer 200) can be lowered by the two-dimensional electron gas, and thereby, the ON resistance of the transistor can be reduced.

Also, according to this configuration, an operation similar to that in the first embodiment is possible, and an effect similar to that in the first embodiment can be obtained.

The field effect transistor can be fabricated according to a method which resembles that described with reference to FIGS. 2A to 2E. That is, the n-type GaN layer 203 and the n-type AlGaN layer 204 may be epitaxially grown in this order on the substrate 12. Also, the n-type GaN layer 401 and the n-type AlGaN layer 402 may be epitaxially grown in this order on the p-type GaN layer 3.

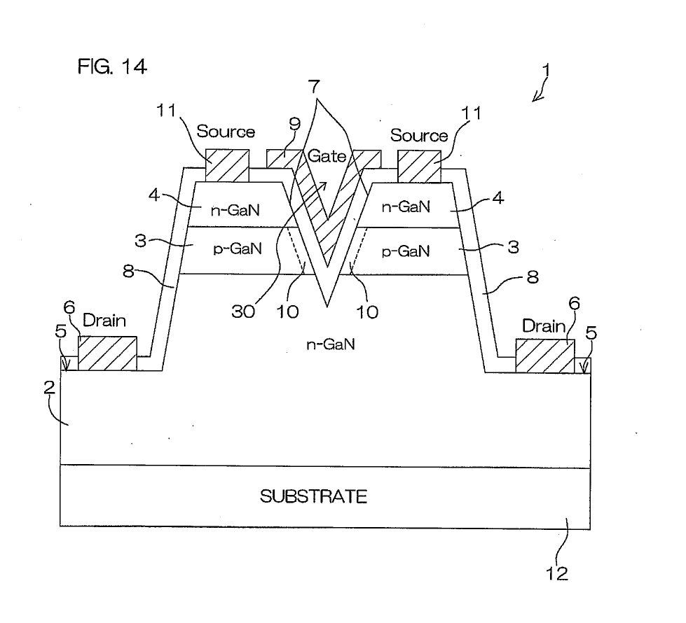

FIG. 14 is a diagrammatic cross-sectional view for describing the structure of a field effect transistor according to a seventh embodiment of the present invention. In FIG. 14, portions corresponding to those shown in the preceding FIG. 1 are shown with the same reference numerals.

In the seventh embodiment, near the middle in the width direction of the nitride semiconductor laminated structure 1, there is formed a trench 30 having a depth that is formed from the n-type GaN layer 4 through the p-type GaN layer 3 to a certain mid-section of the n-type GaN layer 2.

The trench 30 is formed in a V sectional shape, and the inclined side surfaces form the wall surface 7 extending from the n-type GaN layer 2, the p-type GaN layer 3, to the n-type GaN layer 4. Then, the gate insulating film 8 is formed in a region that covers the entire region of the wall surface 7 and that reaches the edge of the trench 30 on the top surface of the n-type GaN layer 4. Further, on the gate insulating film 8, the gate electrode 9 is formed. That is, the gate electrode 9 is opposed to the wall surface 7 via the gate insulating film 8, that is, opposed to the n-type GaN layer 2, the p-type GaN layer 3, and the n-type GaN layer 4, and further, is formed to extend to near the edge of the trench 30 on the top surface of the n-type GaN layer 4.

Also, the trench 30 is arranged at a different location of the drawn section 5 formed with the drain electrode 6. The rest of the configuration is similar to that in the above-described first embodiment, and the operation thereof is also similar thereto.

The trench 30 where the gate insulating film 8 and the gate electrode 9 are formed is arranged at a different location of the drawn section 5, and thus, irrespective of the position at which the drain electrode 6 is placed, the depth of the trench 30 can be properly controlled. By this control, the superficial area of the n-type GaN layer 2 that opposes the gate electrode 9 can be decreased, and thus, the interface charge in the n-type GaN layer 2 can be diminished. As a result, an off-leak current can be decreased, and an ON resistance can be reduced. Moreover, the source, the gate, and the drain are not placed in this order on the same surface, and thus, off characteristics can be improved.

Also, according to this configuration, an operation similar to that in the first embodiment is possible, and an effect similar to that in the first embodiment can be obtained.

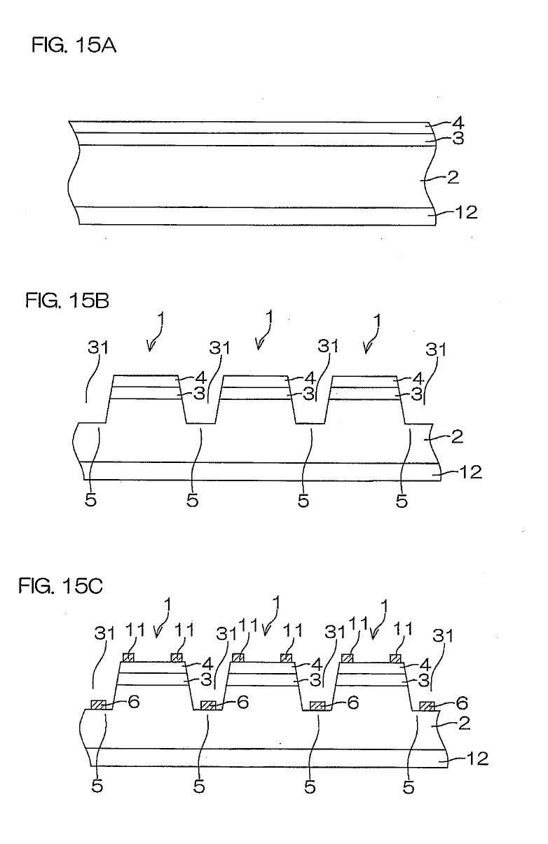

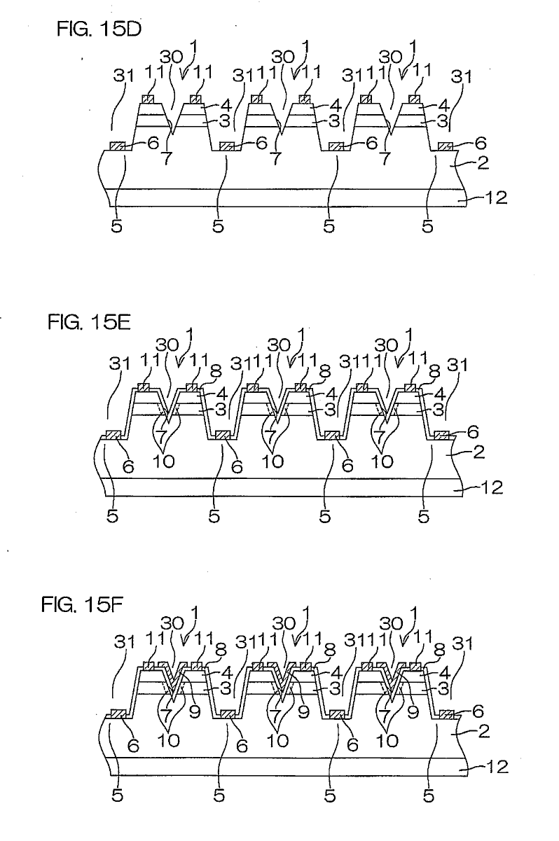

FIG. 15A to FIG. 15F are diagrammatic cross-sectional views each showing a method for manufacturing the field effect transistor in FIG. 14 according to a sequence of steps.

Upon manufacturing this field effect transistor, as shown in FIG. 15A, the n-type GaN layer 2, the p-type GaN layer 3, and the n-type GaN layer 4 are first grown on the substrate 12 in order by an MOCVD growth method, for example. In this way, the nitride semiconductor laminated structure 1 is formed on the substrate 12.

After the formation of the nitride semiconductor laminated structure 1, the nitride semiconductor laminated structure 1 is etched in a stripe pattern, as shown in FIG. 15B. That is, a substantially rectangle sectional groove 31 formed from the n-type GaN layer 4 through the p-type GaN layer 3 to the middle of a layer thickness of the n-type GaN layer 2 is formed by etching. Along with the formation of the groove 31, the drawn section 5 is formed in the nitride semiconductor laminated structure 1.

Next, as shown in FIG. 15C, according to a well-known photolithography technique, a photoresist (not shown) having an opening is formed in a region where the drain electrode 6 and the source electrode 11 should be formed, and a metal (platinum, aluminum, etc, for example) used for materials of these electrodes (6 and 11) is formed by a sputtering method or any other similar method. Subsequently, the photoresist is removed, and thereby, an unnecessary portion of the metal (a portion other than the electrodes (6 and 11)) is lifted off together with the photoresist. Thereby, the drain electrode 6 is formed so as to come into contact with the top surface of the drawn section 5 and the source electrode 11 is formed so as to come into contact with the top surface of the n-type GaN layer 4. After the formation of the drain electrode 6 and the source electrode 11, a thermal alloying (annealing) is performed.

Next, as shown in FIG. 15D, near the middle in the width direction of each nitride semiconductor laminated structure 1, the trench 30 in a V sectional shape is formed along a lengthwise direction of the nitride semiconductor laminated structure 1.

The trench 30 is formed so that the wall surface 7 (side wall of the trench 30) having a plane orientation inclined in a range of 15 to 90 degrees relative to the c-plane (0001) is cut out. Also, the position where the trench 30 is formed is set out so that a dislocation-free region of the p-type GaN layer 3 is exposed from the side wall so as to form the wall surface 7.

Subsequently, on the nitride semiconductor laminated structure 1, the gate insulating film 8 is formed by an ECR sputtering method, for example. Upon the formation of the gate insulating film 8 by the ECR sputtering method, the substrate 12 formed thereon with the nitride semiconductor laminated structure 1 is first put in an ECR deposition apparatus, and is irradiated with an Ar⁺ plasma having energy of approximately 30 eV for several seconds, for example. Irradiation of the Ar⁺ plasma transforms a region near the wall surface 7 in the p-type GaN layer 3, as shown in FIG. 15E, thereby leading to the formation of the region 10 of a p type semiconductor that has conductive characteristics different from those of the p-type GaN layer 3, for example, a lower acceptor concentration than the p-type GaN layer 3 (a fourth-layer forming step).

Thereafter, the gate insulating film 8 that covers the entire surface of the nitride semiconductor laminated structure 1 is formed, and an unnecessary portion (portions of the electrodes (6 and 11)) of the gate insulating film 8 is removed by etching.

Then, as shown in FIG. 15F, by a method similar to that of forming the drain electrode 6 and the source electrode 11, the gate electrode 9 that opposes the wall surface 7 is formed in a manner crossing the gate insulating film 8.

Thus, the field effect transistor of the structure shown in FIG. 14 can be obtained.

The plurality of nitride semiconductor laminated structures 1 formed in a stripe pattern on the substrate 12 each form a unit cell. The gate electrodes 9, the drain electrodes 6, and the source electrodes 11 of the plurality of nitride semiconductor laminated structures 1 are commonly connected to each other at a position not shown. The drain electrode 6 may be shared between the adjacent nitride semiconductor laminated structures 1.

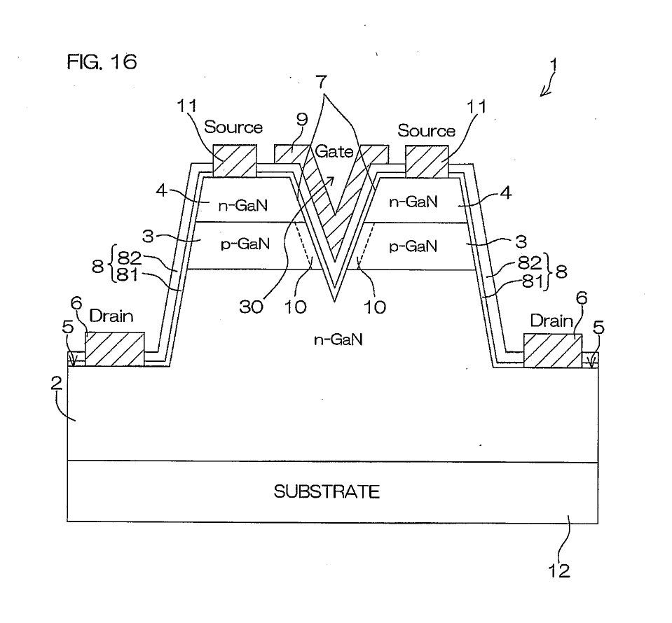

FIG. 16 is a diagrammatic cross-sectional view for describing the structure of a field effect transistor according to an eighth embodiment of the present invention. In FIG. 16, portions corresponding to those shown in the preceding FIG. 15 are shown with same reference numerals.

In the eighth embodiment, in the configuration of the field effect transistor shown in FIG. 15, the gate insulating film 8 is configured of a laminated structure of the silicon nitride film 81 and the silicon oxide film 82, similar to the field effect transistor shown in FIG. 10. The rest of the configuration is similar to those in the preceding first, fourth, and seventh embodiments, and the operation thereof is also similar thereto.

According to this configuration, an operation similar to that in the first embodiment is again possible, and an effect similar to those in the first, fourth, and seventh embodiments can also be obtained.

The field effect transistor can be fabricated according to a method which resembles that described with reference to FIG. 15A to FIG. 15F. That is, upon the formation of the gate insulating film 8, the silicon nitride film 81 and the silicon oxide film 82 may be formed in this order.

Thus, a plurality of embodiments of the present invention are described, and the present invention can be further implemented according to another embodiment.

For example, in the first to eighth embodiments, the method of forming the region 10 by growing the n-type GaN layer 16 is shown only in the first embodiment, as shown in FIG. 3A to FIG. 3E. In the field effect transistors according to the other embodiments (second to eighth embodiments), the region 10 may be formed by growing the n-type GaN layer 16.

Moreover, in the first to eighth embodiments, the source electrode 11 and the drain electrode 6 are formed to come into contact with each of the n-type GaN layers (2 and 4). However, these electrodes 11 and 6 may not contact the n-type GaN layers (2 and 4) as long as conduction is provided to each of the n-type GaN layers (2 and 4). For example, between the source electrode 11 and the drain electrode 6, and each of the n-type GaN layers (2 and 4), a GaN layer may be further intervened.

Moreover, in the first to eighth embodiments, the configuration in which a position at which the source electrode 11 is placed and that at which the drain electrode 6 is placed are switched is shown only in the second embodiment (see FIG. 6). In the field effect transistors according to the other embodiments (first to eighth (other than the second embodiment)), the configuration in which the position at which the source electrode 11 is placed and that at which the drain electrode 6 is placed are switched may be adopted.

### EXAMPLES

Next, the present invention will be described based on Examples and Comparative Examples; the present invention, however, is not limited thereto.

### Example 1 and Comparative Example 1

To confirm an influence on a gate threshold value voltage in a region where a channel is formed (equivalent to the region 10 in FIG. 1. Hereinafter, merely referred to as a “channel forming region”) where a Group III nitride semiconductor layer that is of conductive characteristics and that contains a p-type impurity (hereinafter, simply referred to as a “p-type nitride semiconductor layer”), the analysis of the field effect transistor having a structure shown in FIG. 1 was carried out by a simulation. The simulation conditions are as follows:

### Example 1

### The Surface of the P-Type Nitride Semiconductor Layer is Applied with a Process for Rendering an N-Type

The p-type impurity concentration in the p-type nitride semiconductor layer: 10¹⁸/cm³

The conductive characteristics of the channel forming region: n-type
(film thickness of the channel forming region having an n-type impurity concentration of 10¹⁸/cm³: 0.025 μm)

Film thickness of the gate insulating film: 500 Å

### Comparative Example 1

### The Surface of the P-Type Nitride Semiconductor Layer is not Applied with a Process for Rendering An N-Type

The p-type impurity concentration in the p-type nitride semiconductor layer: 10¹⁸/cm³

The conductive characteristics of the channel forming region: p-type
(Film thickness of the channel forming region having a p-type impurity concentration of 10¹⁸/cm³: 0.025 μm)

Film thickness of the gate insulating film: 500 Å

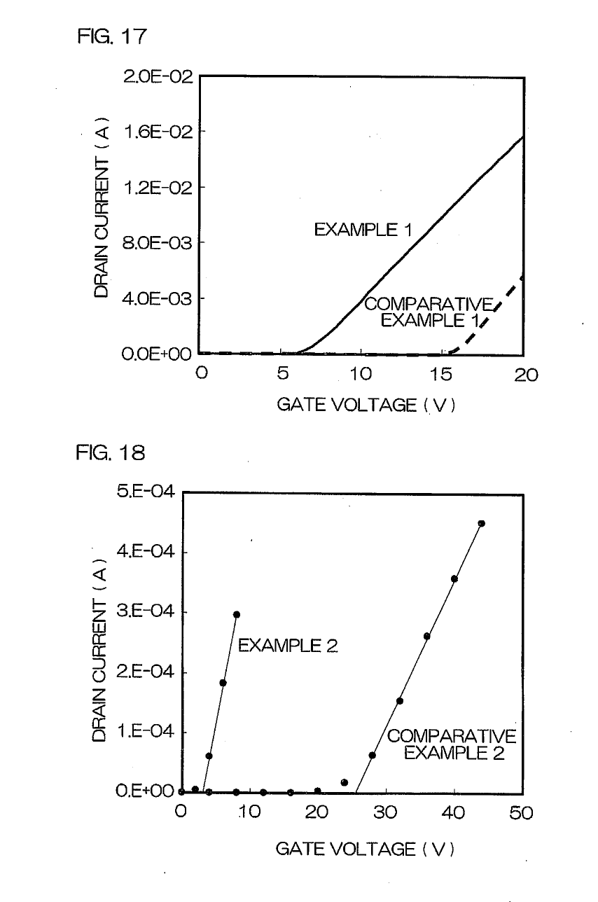

The simulation results under these conditions are shown in FIG. 17. In FIG. 17, curves indicated by a solid line indicate results of the field effect transistor according to Example 1 and those indicated by a dashed line indicate results of the field effect transistor according to Comparative Example 1.

As shown in FIG. 17, the gate threshold value voltage (voltage with which the transistor is turned on) of the field effect transistor according to Example 1 is 6V and that of the field effect transistor of the Comparative Example 1 is 16V. That is, it was confirmed that the gate threshold value voltage of the field effect transistor of Example 1 in which the channel forming region of the p-type nitride semiconductor layer is rendered n-type was lower than that of the field effect transistor of Comparative Example 1.

### Example 2

On the substrate, a GaN nitride semiconductor laminated structure formed of an npn laminated structure (an n-type GaN layer, a p-type GaN layer, and an n-type GaN layer were laminated in order) was formed by a metal organic chemical vapor deposition method (MOCVD method), and thereafter, SiO₂ was film-deposited for 350 nm at an upper section of the n-type GaN layer of the topmost surface by a magnetron sputtering method. Subsequently, a resist was applied on this SiO₂, and patterned by a well-known photolithography technique. By dry-etching using CF₄, the SiO₂ was selectively etched. Thereafter, the resist was removed by ashing.

After the removal of the resist, dry-etching using Cl₂/SiCl₄ was adopted to selectively etch GaN. Thereafter, the SiO₂ was removed by BHF.

Subsequently, the substrate formed thereon with the GaN nitride semiconductor laminated structure was put in an ECR (Electron Cyclotron Resonance) deposition apparatus, and the target (Si) was irradiated with Ar⁺ plasma having energy of 400 eV. On the other hand, while the sample made of GaN was irradiated with Ar⁺ plasma of approximately 30 eV, an SiO₂ film (gate insulating film) was formed on the surface of the GaN nitride semiconductor laminated structure. At an initial stage of forming the SiO₂ film, oxygen was pushed out from the target, and implanted to the p-type GaN layer by energy of approximately 100 eV. Thereby, on the surface of the p-type GaN layer, a region that is of several nm in thickness and that is made of a semiconductor (rendered n-type) was formed.

Then, the gate electrode was arranged so as to oppose the p-type GaN layer in a manner crossing the SiO₂ film. Further, the source electrode was arranged in the upper-sided n-type GaN layer of the p-type GaN layer and the drain electrode was arranged in the lower-sided n-type GaN layer, respectively, thereby fabricating the field effect transistor.

### Example 3

Except that the SiO₂ film (gate insulating film) was formed by a magnetron sputtering method, the field effect transistor was fabricated by a method similar to that in Example 2. Upon the formation of the SiO₂ film by a magnetron sputtering method, a substrate formed thereon with the GaN nitride semiconductor laminated structure was first put in a counter electrode type apparatus, and within the counter electrode type apparatus, an Ar⁺ plasma was produced. Subsequently, the target (SiO₂) was applied with a voltage of 300 V, and the target was irradiated with the produced Ar⁺ plasma. Thereby, the SiO₂ was sputtered to form the SiO₂ film (gate insulating film) on the surface of the GaN nitride semiconductor laminated structure. At this time, oxygen was pushed out from the target, and implanted to the p-type GaN layer by energy of 300 eV. Thereby, on the surface of the p-type GaN layer, a region made of a semiconductor (rendered n-type) was formed.

### Example 4

In addition to the method of fabricating the field effect transistor similar to that in Example 2, the surface of the p-type GaN layer was ion implanted before the formation of each electrode (the gate, the source, and the drain). During the ion implantation, the entire nitride semiconductor device was implanted with ions (Si ions) at room temperature (acceleration energy of 80 eV; an implantation amount of 10¹⁵/cm²). Thereafter, the resultant element was applied with a thermal process at 1200° C. Thereby, on the surface of the p-type GaN layer, a region made of a semiconductor (rendered n-type) was formed. It should be noted that in the Example 4, even when O ions are used instead of the Si ions, a region made of a semiconductor (rendered n-type) can be formed on the surface of the p-type GaN layer.

### Example 5

In addition to the method of fabricating the field effect transistor similar to that in Example 2, the surface of the p-type GaN layer was irradiated with an electron beam before the formation of each electrode (the gate, the source, and the drain). During irradiation of the electron beam, the entire nitride semiconductor device was first irradiated with an electron beam for 60 seconds by an acceleration voltage of 30 eV. Thereby, on the surface of the p-type GaN layer, a region made of a semiconductor (rendered n-type) was formed. In addition, as the electron beam, plasma may be used. In this case, it is possible to use an electron generated by an ECR (Electron Cyclotron Resonance).

### Example 6

According to the method similar to that of Example 2, a GaN nitride semiconductor laminated structure was formed on a substrate, and the GaN nitride semiconductor laminated structure was further dry-etched. After the dry-etching, by an MOCVD method (Metal Organic Chemical Vapor Deposition method), a GaN layer that scarcely contains an impurity was grown by 10 nm from the surface of the GaN nitride semiconductor laminated structure. Thereafter, according to the method similar to that of Example 2, the gate insulating film, the gate electrode, the source electrode, and the drain electrode were formed. When the GaN layer scarcely containing an impurity was grown, a region made of an i-type semiconductor was formed on the surface of the p-type GaN layer.

### Comparative Example 2

Except that the SiO₂ film (gate insulating film) was formed by a PECVD method (Plasma Enhanced Chemical Vapor Deposition method), the field effect transistor was fabricated by a method similar to that in Example 2.

Measurement of Gate Voltage-Drain Current Characteristics

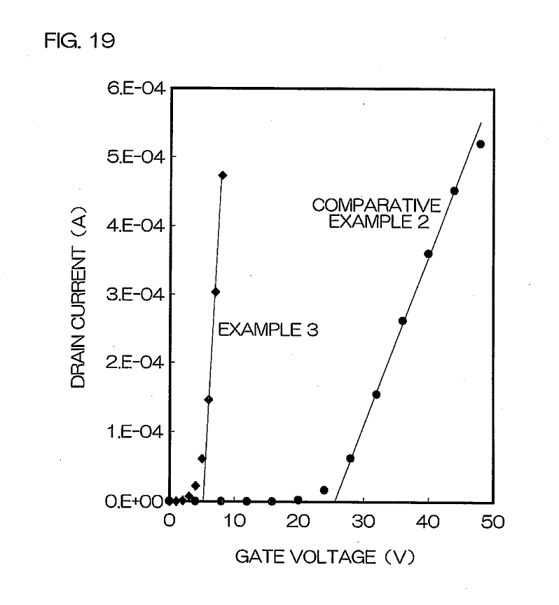

The Example 2, Example 3, and Comparative Example 2 were measured for gate voltage-drain current characteristics. Results of Example 2 and Comparative Example 2 are shown in FIG. 18. Also, results of Example 3 and Comparative Example 2 are shown in FIG. 19. As shown in FIG. 18, a gate threshold value voltage (voltage with which the element is turned on) of the field effect transistor of Example 2 is 2.96V, and that of the field effect transistor of Comparative Example 2 is 25.5V. Also, as shown in FIG. 19, a gate threshold value voltage of the field effect transistor of Example 3 is 5.12V, and that of the field effect transistor of Comparative Example 2 is 25.5V, which is similar to FIG. 18. It was thereby confirmed that the gate threshold value voltage of the field effect transistor having a p-type GaN layer of which the surface is formed with a region made of a semiconductor (rendered n-type) is lower.

Although the embodiments of the present invention are described in detail, these embodiments are merely specific examples used for clarifying the technical contents of the present invention. Therefore, the present invention should not be construed as being limited in any way to these specific examples. The spirit and scope of the present invention are limited only by the scope of the appended claims.

This application corresponds to Japanese Patent Applications No. 2007-16775 and 2007-56429 filed with the Japan Patent Office on Jan. 26, 2007 and Mar. 6, 2007, the full disclosure of which is incorporated herein by reference.

1. A nitride semiconductor device, comprising:
a nitride semiconductor laminated structure including an n-type first layer, a second layer that contains a p-type impurity and that is laminated on the first layer, and an n-type third layer laminated on the second layer, each layer of the nitride semiconductor laminated structure being made of a Group III nitride semiconductor, the nitride semiconductor laminated structure having a wall surface extending from the first, second, to third layers;
a fourth layer formed on the wall surface in the second layer and having a different conductive characteristic from that of the second layer;
a gate insulating film formed so as to contact the fourth layer; and
a gate electrode formed as facing the fourth layer with the gate insulating film being sandwiched between the gate electrode and the fourth layer.

2. The nitride semiconductor device according to claim 1, wherein the fourth layer is formed of a p-type semiconductor having an acceptor concentration lower than an acceptor concentration of the second layer.

3-5. (canceled)

6. The nitride semiconductor device according to claim 1, wherein the gate insulating film is formed so as to contact the first layer or the third layer on the wall surface, and the gate electrode is formed as facing the first or third layer on the wall surface with the gate insulating film being sandwiched between the gate electrode and the first or third layer.

7. The nitride semiconductor device according to claim 1, wherein the first layer includes a lower layer and an upper layer that has an impurity concentration smaller than that of the lower layer and that is crossed by the lower layer and the second layer.

8. The nitride semiconductor device according to claim 1, further comprising a drain electrode electrically connected to the first layer and a source electrode electrically connected to the third layer.

9. The nitride semiconductor device according to claim 1, further comprising:
a trench that reaches from the third layer through the second layer to the first layer and that has a side wall configuring the wall surface; and
a second trench that is formed so as to reach at least the first layer and that is different from the trench, wherein
on a bottom surface of the second trench, a drain electrode is formed.

10. The nitride semiconductor device according to claim 1, further comprising a source electrode electrically connected to the first layer and a drain electrode electrically connected to the third layer.

11. The nitride semiconductor device according to claim 1, wherein the nitride semiconductor laminated structure is formed on the insulative substrate.

12. The nitride semiconductor device according to claim 11, wherein the drain electrode or the source electrode is formed on a surface of the nitride semiconductor laminated structure of which the surface is exposed by removing the insulative substrate.

13. The nitride semiconductor device according to claim 1, wherein the nitride semiconductor laminated structure is formed on one surface of an electrically conductive substrate, and the drain electrode or the source electrode is formed on an alternate surface of the electrically conductive substrate.

14. (canceled)

15. The nitride semiconductor device according to claim 1, wherein the first, second, and third layers are laminated so that a c-plane is a main surface.

16. (canceled)

17. The nitride semiconductor device according to claim 1, wherein the wall surface of the nitride semiconductor laminated structure is a semi-polar plane.

18. The nitride semiconductor device according to claim 1, wherein the wall surface of the nitride semiconductor laminated structure is an m-plane or an a-plane.

19. The nitride semiconductor device according to claim 1, wherein the third layer is a layer obtained by laminating a plurality of layers having different compositions.

20. The nitride semiconductor device according to claim 1, wherein the first layer is a layer obtained by laminating a plurality of layers having different compositions.

21. A nitride semiconductor device, comprising:
a nitride semiconductor laminated structure including an n-type first layer, a second layer that contains a p-type impurity and that is laminated on the first layer, and an n-type third layer laminated on the second layer, each layer of the nitride semiconductor laminated structure being made of a Group III nitride semiconductor, the nitride semiconductor laminated structure having a wall surface extending from the first, second, to third layers;
a fourth layer formed on the wall surface in the second layer and having a different conductive characteristic from that of the second layer formed;
a gate insulating film formed so as to contact the fourth layer; and
a gate electrode formed as facing the fourth layer so that the gate insulating film is crossed, wherein
the gate insulating film contains a nitride or an oxide, and a insulating film contacting the wall surface is a nitride.

22. The nitride semiconductor device according to claim 21, wherein the nitride is a silicon nitride and the oxide is a silicon oxide.

23-24. (canceled)

25. A nitride semiconductor package, comprising:
a package housing, formed of an electrically conductive material, for loading and mounting a semiconductor element; and
a nitride semiconductor device according to claim 1 of which a source electrode is loaded on the package housing so as to come into contact with the package housing.

26-34. (canceled)
